(19) United States
(12) Patent Application Publication
(10) Pub. No.: US 2017/0097630 A1
(43) Pub. Date: Apr. 6, 2017

(54) SHADOW SPHERE LITHOGRAPHY

(71) Applicant: President and Fellows of Harvard College, Cambridge, MA (US)

(72) Inventors: Alex NEMIROSKI, Cambridge, MA (US); Mathieu GONIDEC, Cambridge, MA (US); George M. WHITESIDES, Newton, MA (US); Jerome M. FOX, Cambridge, MA (US)

(21) Appl. No.: 15/127,915

(22) PCT Filed: Mar. 24, 2015
(86) PCT No.: PCT/US2015/022242

§ 371 Date: Sep. 21, 2016

Related U.S. Application Data
(60) Provisional application No. 61/969,399, filed on Mar. 24, 2014.

(51) Int. Cl. G05B 19/4097; B33Y 50/02; G03F 7/00; B33Y 10/00

(52) U.S. Cl. CPC G05B 19/4097; B33Y 10/00; B33Y 50/02; G03F 7/0002

(57) ABSTRACT

Systems and methods of determining operation parameters for the shadow cast fabrication of micro or nanostructures, the fabrication process using deposition from at least one source over an array of particles, wherein the deposition produces overlapping shadows masking the substrate. A computing device receives a first set of parameter inputs defining particle properties and deposition properties in a shadow cast fabrication, generates data corresponding to a first image for display based on the first set of parameters, receives at least one incremental parameter input that modifies or adds to the first set of parameter inputs, dynamically generates data corresponding to at least one second image for display based on the at least one incremental parameter input, receives an indication that the at least one second image corresponds to a shape ready for fabrication, and generates an output set of fabrication parameters corresponding to the shape ready for fabrication.

### STATEMENT OF INCORPORATION BY REFERENCE

This application claims priority to U.S. Application No. 61/969,399, entitled “Shadow Sphere Lithography,” filed Mar. 24, 2014, the contents of which are incorporated herein in their entirety.

### STATEMENT OF FEDERAL SUPPORT

This invention was made with government support under Office of Naval Research Grant No. N00014-10-1-0942 and under NSF award no. ECS-0335765. The government has certain rights in this invention.

### TECHNICAL FIELD OF THE INVENTION

This invention relates generally to a method and apparatus of designing and fabricating metasurfaces.

### BACKGROUND OF THE INVENTION

Metasurfaces are an emergent class of ultrathin (sub-wavelength), nanostructured materials that enable the manipulation of light, acoustic waves and heat flows in ways not possible with naturally occurring materials—either in bulk or at interfaces. These materials can be engineered to display a range of exotic properties that will enable, for example, frequency selective surfaces (FSS), circular polarizers, optical switching, super-resolution imaging, flat lenses, beam steering, ultra-sensitive biosensing, efficient light concentration, and quantum information processing. It has, however, been impossible or impractical to fabricate many of the theoretical designs, thus preventing an efficient exchange between theory and experiment that is necessary to optimize these materials and integrate them into functional devices.

For example, conventional, top-down approaches (such as photo-, electron beam, or ion beam lithography) can be (1) too slow (days to weeks), (2) too complicated (e.g., requiring multiple registration and lithography steps, especially for multi-material devices), and/or (3) too expensive (requiring highly sophisticated equipment and facilities) to facilitate rapid evaluation of theoretical designs. Moreover, their many unconventional variations do not have sufficient resolution of features, scalability, and design flexibility to serve as a general solution for the needs of optical metasurfaces, either in research or large-scale production.

One alternative uses a self-assembled array of colloidal micro- or nanospheres as a shadow mask to eliminate the often difficult, time-consuming, and costly step of generating (and registering) a shape-specific stencil, referred to as nanosphere lithography (NSL) or colloidal lithography. While nanosphere lithography has the capability of producing periodic structures with small features that are packed closely together, it has insufficient flexibility of design for general application to the development of metasurfaces and has only produced a narrow range of simple patterns.

### SUMMARY

In some embodiments, a method is described for determining operation parameters for the shadow cast fabrication of micro or nanostructures, the fabrication process using deposition from at least one source over an array of particles, wherein the deposition produces overlapping shadows masking the substrate, the method comprising receiving, at a user interface, a first set of parameter inputs defining particle properties and deposition properties in a shadow cast fabrication, wherein the parameter inputs include one or more of particle size, gap between the particles, and location of the at least one source; calculating, at a processor configured to store and execute computer readable instructions, and displaying on a display device a first image corresponding to the first set of parameters; receiving, through the user interface, at least one incremental parameter input that modifies or adds to the first set of parameter inputs; dynamically calculating and displaying at least one second image corresponding to the at least one incremental parameter input; receiving, through the user interface, an indication that the at least one second image corresponds to a shape ready for fabrication; and displaying on a display device an output set of fabrication parameters corresponding to the shape ready for fabrication. In some embodiments, the method further comprising transmitting the output set of fabrication parameters to a fabrication machine for fabrication of the shape. In some embodiments, the gap between the particles corresponds to parameters comprising gas flow rate, RF power, length of etch. In some embodiments, the location of the at least one source comprises at least one angle. In some embodiments, the at least one angle is adjustable.

In some embodiments, a system is described for determining operation parameters for the shadow cast fabrication of micro or nanostructures, the fabrication process using deposition from at least one source over an array of particles, wherein the deposition produces overlapping shadows masking the substrate, the system comprising a user interface, for inputting parameter inputs defining particle properties and deposition properties in a shadow cast fabrication; program code on a computer readable medium, which when executed on a computer system performs functions including receiving, at a user interface, a first set of parameter inputs defining particle properties and deposition properties in a shadow cast fabrication, wherein the parameter inputs include one or more of particle size, gap between the particles, and location of the at least one source; calculating, at a processor configured to store and execute computer readable instructions, and displaying on a display device a first image corresponding to the first set of parameters; receiving, through the user interface, at least one incremental parameter input that modifies or adds to the first set of parameter inputs; dynamically calculating and displaying at least one second image corresponding to the at least one incremental parameter input; receiving, through the user interface, an indication that the at least one second image corresponds to a shape ready for fabrication; and displaying on a display device an output set of fabrication parameters corresponding to the shape ready for fabrication. In some embodiments, the gap between the particles corresponds to parameters comprising gas flow rate, RF power, length of etch. In some embodiments, the location of the at least one source comprises at least one angle. In some embodiments, the at least one angle is adjustable.

In some embodiments, a method of fabricating metasurfaces is described comprising depositing particles on a substrate; performing an isotropic etch to form a gap between the particles; mounting the substrate on a rotation stage; and exposing the substrate to at least one deposition source, wherein size of the particles, the gap between the particles and the location of the at least one source are generated by the methods described for determining operation parameters for the shadow cast fabrication of micro or nanostructures.

In some embodiments, a computerized method is described for determining operation parameters for the shadow cast fabrication of micro or nanostructures, the fabrication process using deposition from at least one source over an array of particles, wherein the deposition produces overlapping shadows masking the substrate. In some embodiments, the method comprises receiving, at a computing device, a first set of parameter inputs defining particle properties and deposition properties in a shadow cast fabrication, wherein the parameter inputs include one or more of particle size, gap between the particles, location of the particles, and location of the at least one source; generating, by the computing device, data corresponding to a first image for display on a display device based on the first set of parameters; receiving, by the computing device, at least one incremental parameter input that modifies or adds to the first set of parameter inputs; dynamically generating, by the computing device, data corresponding to at least one second image for display on the display device based on the at least one incremental parameter input; receiving, by the computing device, an indication that the at least one second image corresponds to a shape ready for fabrication; and generating, by the computing device, an output set of fabrication parameters corresponding to the shape ready for fabrication.

In some embodiments, the computerized method further comprises transmitting the output set of fabrication parameters to a fabrication machine for fabrication of the shape. In some embodiments, the gap between the particles corresponds to parameters comprising gas flow rate, RF power, length of etch. In some embodiments, the location of the at least one source comprises at least one angle. In some embodiments, the at least one angle is adjustable. Inn some embodiments, the location of the particles define one of an aperiodic and a quasi-periodic structure. In some embodiments, the output parameters comprise at least one of a diameter of the particle, an etch time, and one or more deposition angles.

In some embodiments, a system is described for determining operation parameters for the shadow cast fabrication of micro or nanostructures, the fabrication process using deposition from at least one source over an array of particles, wherein the deposition produces overlapping shadows masking the substrate. In some embodiments, the system comprises a processor; and

a memory coupled to the processor and including computer-readable instructions that, when executed by a processor, cause the processor to receive a first set of parameter inputs defining particle properties and deposition properties in a shadow cast fabrication, wherein the parameter inputs include one or more of particle size, gap between the particles, location of the particles, and location of the at least one source; generate data corresponding to a first image for display on a display device based on the first set of parameters; receive at least one incremental parameter input that modifies or adds to the first set of parameter inputs; dynamically generate data corresponding to at least one second image for display on the display device based on the at least one incremental parameter input; receive an indication that the at least one second image corresponds to a shape ready for fabrication; and generate an output set of fabrication parameters corresponding to the shape ready for fabrication.

In some embodiments, the gap between the particles corresponds to parameters comprising gas flow rate, RF power, length of etch. In some embodiments, the location of the at least one source comprises at least one angle. In some embodiments, the at least one angle is adjustable. In some embodiments, the output set of fabrication parameters comprise at least one of a diameter of the particle, an etch time, and one or more deposition angles. In some embodiments, the location of the particles define one of an aperiodic and a quasi-periodic structure.

In some embodiments, a method is described for fabricating metasurfaces. In some embodiments, the method comprises depositing particles on a substrate; performing an isotropic etch to form a gap between the particles; mounting the substrate on a rotation stage; and exposing the substrate to at least one deposition source, wherein size of the particles, the gap between the particles and the location of the at least one source are generated by a computerized method described herein. In some embodiments, the particles comprise polystyrene.

In some embodiments, a method is described for fabricating metasurfaces. In some embodiments, the method comprises etching holes into a substrate; placing particles into the holes; transferring the particles to a target material; mounting the target material on a rotation stage; and exposing the target material to at least one deposition source, wherein size of the particles, gap between the particles and location of the at least one source are generated by the computerized methods described herein. In some embodiments, the target material comprises one of Polydimethylsiloxane (PDMS) and a silicon wafer. In some embodiments, the particles comprise a diameter smaller than a diameter of the holes. In some embodiments, the diameter of the particles is approximately 90% of the diameters of the holes. In some embodiments, the particles comprise silica. In some embodiments, placing the particles into the holes further comprises rubbing adhesive onto the template prior to placing the particles into the holes; and removing the adhesive after placing the particles into the holes by applying a heating source sufficient to vaporize the adhesive without damaging the particles. In some embodiments, the adhesive is polyethyleneimine (PEI).

Shadow sphere lithography can bridge the divide between structures that are desired to test theory, and structures that can be made in practice, by combining a formalized methodology to build-up intricate patterns from simple features with a simple scheme for fabrication. Shadow sphere lithography can provide a general solution for the fabrication of periodic metasurfaces, in part, because (1) it can be used to generate closely-packed, periodic arrays of unit cells with small feature-size (>10 nm) with the flexibility to pattern many of the complex structures useful to the realization of metasurfaces, (2) it allows the unit cell to be rationally designed and altered to suit the needs of the intended device, (3) it allows devices to be fabricated rapidly and efficiently simply by rotating a stage, during PVD, to the angles of deposition predicted by the design, (4) it can use a single universal mask that requires a minimum of customization (only plasma etching) that even enables multiple materials to be deposited in different locations the metasurface, without the need for fabricating or registering of a new mask, (5) it allows designs to be easily scaled up or down simply by changing the size of the spheres used to generate the MCC mask, and (6) it can greatly reduce the length of the development cycle from theory, to design, to fabrication, to characterization, and back to theory.

Simple patterns produced by shadow sphere lithography represent special cases of a vast parameter space of possible shadows. A hexagonally non-close-packed (HNCP) array of spheres can provide a nearly universal stencil in part because (1) the relatively small contact-area of a sphere resting on a flat substrate can obscure very little of the substrate from possible line of sight and hence patterning, and (2) the fill-factor of an HNCP array of spheres can offer a high density of available narrow gaps for casting, and overlaying, many different shadows. These characteristics, coupled with the six-fold rotation symmetry of a hexagonal lattice, can enable a sphere-based shadow mask to pattern nearly anywhere within the unit cell.

### BRIEF DESCRIPTION OF THE DRAWINGS

FIG. 1A shows a screenshot of an embodiment of a shadow sphere lithography design program, according to some embodiments of the present disclosure.

FIG. 1B shows an expanded view of a drop-down menu with templates, according to some embodiments of the present disclosure.

FIG. 2A is a schematic illustration showing generation of a single nanostructure or an array of nanostructures using a single angle of deposition, according to some embodiments of the present disclosure.

FIG. 2B is a schematic illustration showing an exemplary complex design using multiple angles of deposition that can be obtained using the computer-assisted model described herein, according to some embodiments of the present disclosure.

FIGS. 2C-E is a computer generated series of shapes that illustrate how features created by a single polar angle θ of deposition can be used generate complex designs, according to some embodiments of the present disclosure.

FIGS. 2F-H show experimentally realized samples that demonstrate the overlay of theoretically predicted phases in FIGS. 2C-E, according to some embodiments of the present disclosure.

FIGS. 3A-C show a coordinate system, a projection surface, and the elliptical shadow cast onto the surface by a projection source located at an angle (θ, φ), according to some embodiments of the present disclosure.

FIG. 4A shows five geometrical phases possible with a single angle of projection, according to some embodiments of the present disclosure.

FIG. 4B shows how phases transform into each other when the angles are changed, including a representative group of features that demonstrate the ability to tune the orientation, size, and shape, of single lines and line segments, by variation of a polar or azimuthal angle of projection, according to some embodiments of the present disclosure.

FIG. 4C shows the dependence of the feature width of projected tripods on the gap distance between the nearest neighboring spheres and shows the different tripod sizes at different gap widths, according to some embodiments of the present disclosure.

FIG. 5(a) shows a method of generating multi-material tripods, according to some embodiments of the present disclosure.

FIGS. 5(b), (c), and (f) show tripods with various extra features that can help tune the resonance and improve coupling between the structures (six sources), according to some embodiments of the present disclosure.

FIG. 5(d) shows a pinwheel structure (three sources), according to some embodiments of the present disclosure.

FIG. 5(e) shows isolated transistor-like structures (three sources), according to some embodiments of the present disclosure.

FIG. 5(g) shows an “X” geometry (six sources), according to some embodiments of the present disclosure.

FIG. 5(h) shows Split-Ring resonators composed of isolated line segments (five sources), according to some embodiments of the present disclosure.

FIG. 5(i) shows interpenetrating tripod arrays (six sources), according to some embodiments of the present disclosure.

FIG. 6(a) shows an array consisting of three types of parallelograms (12 sources), according to some embodiments of the present disclosure.

FIG. 6(b) shows four sources removed to generate an array with only two types of parallelograms (8 sources), according to some embodiments of the present disclosure.

FIG. 6(c) shows antisymmetric variations with two more sources removed (6 sources), according to some embodiments of the present disclosure.

FIG. 6(d) shows symmetric variations with two more sources removed (6 sources), according to some embodiments of the present disclosure.

FIG. 7(a) shows snowflakes connected with dotted traces, according to some embodiments of the present disclosure.

FIG. 7(b) shows a complex shape, according to some embodiments of the present disclosure.

FIG. 7(c) shows snowflakes with end-caps, according to some embodiments of the present disclosure.

FIG. 7(d) shows three levels of nested structures: a star within a circle within a series of interconnected lines, according to some embodiments of the present disclosure.

FIG. 7(e) shows a double nested star configuration, according to some embodiments of the present disclosure.

FIG. 8(a) shows interconnected nano-antennas, according to some embodiments of the present disclosure.

FIG. 8(b) shows addressable tripod arrays, according to some embodiments of the present disclosure.

FIG. 8(c) shows complex overlapping rings, according to some embodiments of the present disclosure.

FIG. 8(d) shows addressable junctions, according to some embodiments of the present disclosure.

FIG. 9A shows examples of metasurfaces fabricated by composing two to three different angles of deposition, according to some embodiments of the present disclosure.

FIG. 9B shows devices formed by three to four angles of deposition, according to some embodiments of the present disclosure.

FIG. 9C shows devices formed by five to six different angles of deposition, according to some embodiments of the present disclosure.

FIG. 9D shows a subset of possible unit cells categorized according to optical function, according to some embodiments of the present disclosure.

FIG. 10A shows an array of chiral, tripolar structures (formed by three asymmetric bars) fabricated with each bar composed of Au, Ag, and Pt, according to some embodiments of the present disclosure.

FIG. 10B shows an array of chiral, hexagonal structures (formed by six asymmetric bars) fabricated with each bar composed of Cu, Ti, Cr, Co, Ge, or Ni, according to some embodiments of the present disclosure.

FIG. 11 shows SEM images of assorted single material devices (all Ag) fabricated with 2-6 different angles of deposition, according to some embodiments of the present disclosure.

FIG. 12 shows SEM images of assorted multi-material devices fabricated with 2-3 different angles of deposition, according to some embodiments of the present disclosure.

FIG. 13A shows a 3D scheme for a four-sided “looped” array of nanoantennas, according to some embodiments of the present disclosure.

FIG. 13B shows the orientation (relative to the initial design) of three domains on the same substrate, according to some embodiments of the present disclosure.

FIG. 13C shows the designed structure rendered by optical ray tracing, according to some embodiments of the present disclosure.

FIG. 13D shows an SEM image of the fabricated sample, according to some embodiments of the present disclosure.

FIG. 13E shows the FTIR corresponding to the SEM image in FIG. 13D, according to some embodiments of the present disclosure.

FIG. 13F shows the simulated spectra corresponding to the SEM image in FIG. 13D, according to some embodiments of the present disclosure.

FIGS. 13G-N show modeled, imaged, characterized, and simulated data correspond to two other randomly oriented domains on the same substrate, according to some embodiments of the present disclosure.

FIG. 14A shows a schematic of an embodiment of the 2-axis rotation stage, according to some embodiments of the present disclosure.

FIG. 14B-C show images of an embodiment of an electron beam evaporation system with external knobs for manipulating a rotation stage, according to some embodiments of the present disclosure.

FIG. 14D shows an image one embodiment of the rotation stage mounted inside the vacuum chamber of a deposition system, one embodiment for a connection between the rotation stage and the external knob with a flexible shaft and feed-through, according to some embodiments of the present disclosure.

FIGS. 15 A-B show a Penrose tiling of spheres and the corresponding projected pattern of shadows, according to some embodiments of the present disclosure.

FIG. 16 shows a screenshot of an embodiment of a shadow sphere lithography design program, according to some embodiments of the present disclosure.

FIG. 17 shows modeled patterns of 15 different quasicrystalline metasurfaces created with five different angles of depositions at φ=72° increments, according to some embodiments of the present disclosure.

FIGS. 18A-E show a fabrication process and templated spheres, according to some embodiments of the present disclosure.

### DETAILED DESCRIPTION OF THE INVENTION

A technique for versatile nanofabrication of nanostructures using Shadow Sphere Lithography (SSL) is described.

Metasurfaces are a class of ultrathin (sub-wavelength), nanostructured materials that enable the manipulation of light, acoustic waves and heat flows in ways not possible with naturally occurring materials. By controlling the size, shape, material composition, and arrangement of the “unit cells” on a metasurface, it is possible to manipulate the properties (e.g., frequency, phase, and polarization) of the light that interacts with the metasurface. In one embodiment, a metasurface can comprise conductive nanoantennas, which are planar, periodic array of rationally designed building blocks that can couple to incident electromagnetic radiation through a plasmonic resonance.

Metasurfaces have the potential to revolutionize photonics by yielding on-chip, planar optical devices (e.g. frequency-selective surfaces, circular polarizers, beam steerers, lenses, analog optical computers) with applications to super resolution imaging, efficient solar harvesting, and quantum information processing. The exploration of these devices and the integration of theory and experiment to predict their performance in efficient, functional devices has been slow, in major part because, it has been difficult to fabricate the intricate, finely-featured structures they require, such as the elaborate arrays of plasmonic antennas.

### Shadow Sphere Lithography With Periodic Structures

In a shadow lithography procedure, a 2D colloidal crystal is used as a mask for material deposition. Shadow sphere lithography is both a bottom-up and top down approach to patterning nanostructures on solid surfaces. The self-assembly of particles (also referred to herein as “spheres”) disclosed herein is a bottom up approach, while the deposition and etching of the particles is a top-down approach. Shadow sphere lithography exploits the self-organization of colloidal particles on a surface, for example, into a hexagonally close-packed (HCP) layer. Particle diameters can range from 10 nm to a few micrometers. When the hexagonally close-packed layer is formed on a solid substrate, the space between each triplet of spheres can be regarded as a mask opening. The shape and spacing of the particles can be modified by adding or removing material using deposition and etching techniques. Deposition methods such as physical deposition using an electron-beam evaporation can be used. During deposition, the particles block or ‘shadow’ the substrate from the depositing material and projection of the interstices between ordered close-packed particles defines the shape of the material deposited on substrates. While some embodiments of the present disclosure describe techniques using spheres, other types of particles can also be used (e.g., cubes, pyramids, tetrahedra).

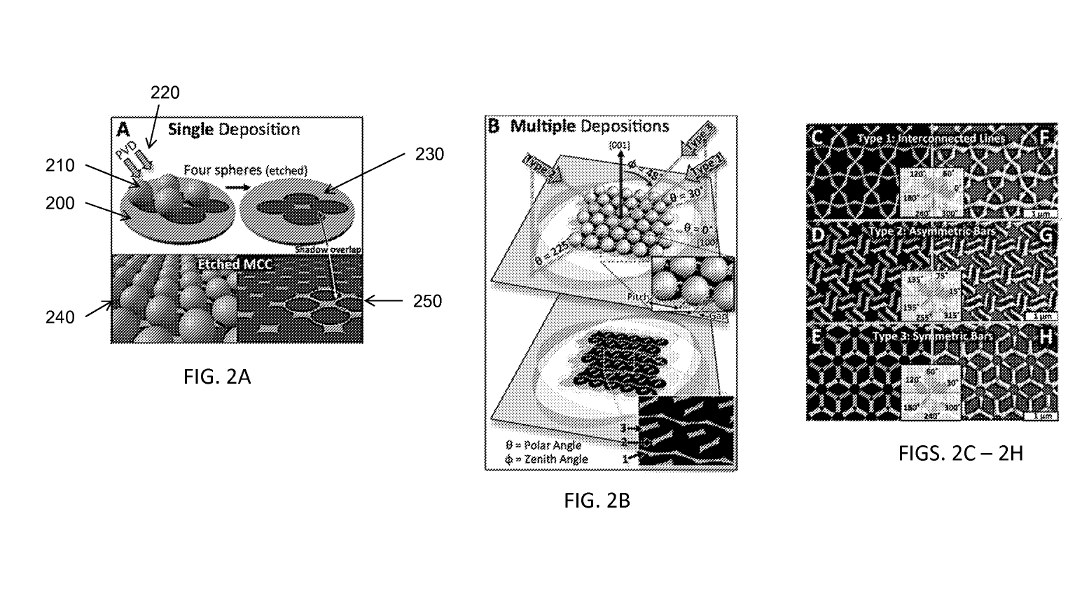

FIG. 2A demonstrates this technique and shows generation of a single nanostructure or an array of nanostructures using a single angle of deposition. Specifically, FIG. 2A shows a surface 200 having four hexagonally non-close-packed (HNCP) spheres 210 positioned relative to a source 220 for physical vapor deposition. The shadows of four, hexagonally non-close-packed (HNCP) spheres overlap to form an isolated rectangular strip, or “bar”, 230 that is exposed. FIG. 2A also shows a surface 240 having an array hexagonally non-close-packed (HNCP) spheres 250, and illustrates how an array of such spheres can generate an array of bars 260.

The shape of the nanoparticles and the spacing of the nearest neighboring particles control the projection of the interstices of the colloidal crystals on substrates. They can be tuned by varying the projection angle of the incident vapor beam on the substrates or by reducing the particle diameter of the assembled particles, for instance. Material deposited at normal incidence to a self-assembled, hexagonally close-packed (HCP) monolayer colloidal crystal generate an array of triangular nanoparticles on the underlying substrate. It is also possible to generate a honeycomb pattern by etching the monolayer colloidal crystal with oxygen plasma, before deposition, to reduce the diameters of (and open gaps between) the spheres without changing the spacing of the lattice. Although some simple variations on these patterns have been demonstrated by angled deposition and/or etching through the monolayer colloidal crystal, the parameter space is not well understood, and this approach has remained relatively unexplored.

To achieve an adequate level of control, designs for photonic applications typically specify intricate surface patterns with very fine features (˜λ/20) contained within unit cells that are packed at high-density (<λ/2). While existing approaches to fabrication are sufficient for applications beyond the far-infrared (λ>15 μm), fabrication becomes increasingly problematic for optical applications in the visible to mid-infrared (λ=0.4−8 μm). Furthermore, as designs required for photonic applications become more complex, the specific deposition sequences needed to prepare complex structures using simple shadow deposition techniques are not available. Trial and error is not a viable approach given the almost limitless combinations that need to considered and rejected before arriving at an acceptable model.

According to one or more embodiments, complex nanostructures that are not capable of design by simple deposition can be formed in a two-step process that includes computer-implemented design and fabrication. As described herein, a design of numerous metasurfaces of varying complexity and material composition can be developed using versatile, computer-implemented design rules. A deposition system, receiving instructions from the computer-implemented design, can also be used to fabricate those designs rapidly (˜several hours per device) using physical vapor deposition techniques. Using sequential deposition from multiple angles through a monolayer colloidal crystal, shadow sphere lithography produces an extensive variety of complex patterns that have not previously been realized physically or considered theoretically.

With the aid of the computer program described herein, a vast parameter space of shadow-derived shapes (e.g., using methods from optical ray tracing) are made available, which enables the rational design and fabrication of myriad, sophisticated metasurfaces with useful geometries. The program provides a seamless user experience that eliminates the need to consider multi-angled shadows while designing structures.

Shadow sphere lithography can provide a process that is versatile and that provides rapid access to an unlimited variety structures, including multi-material structures. The process does not require sophisticated equipment. Countless structural variations of deposited patterns can be fabricated using a mechanical rotation stage and an electron-beam evaporator. The structural variations offered by the polycrystalline arrangement of domains in a self-assembled monolayer colloidal crystal can be used for device discovery.

### Generating Metastructure Designs

In one or more embodiments, a computer-assisted model is used to generate deposition parameters for use in a shadow sphere lithography deposition of nanostructures. In some embodiments, the input to the program comprises a visual or numerical representation of a shadow shape. The program can receive the input through a user interface. In some embodiments, the output to the program comprises parameters (e.g., pitch, gap, angles, etc.) corresponding to the shape. The outputs can be sent to a plasma etching system and a deposition system for fabrication.

The program uses a set of parameters that define aspects of the colloidal particles, such as particle size, particle packing geometry and spacing between particles. Any or all of the particle parameters can be variable or fixed. The program also uses a set of parameters that define aspects of the incident light on the particles that casts a shadow, such as an angle of inclination from a crystal axis (the polar angle φ) and the azimuthal angle, θ, measured counterclockwise from a crystal axis. The light casting parameters are associated with a deposition source in the fabrication of the actual metastructures. Typically, the light casting parameters are variable.

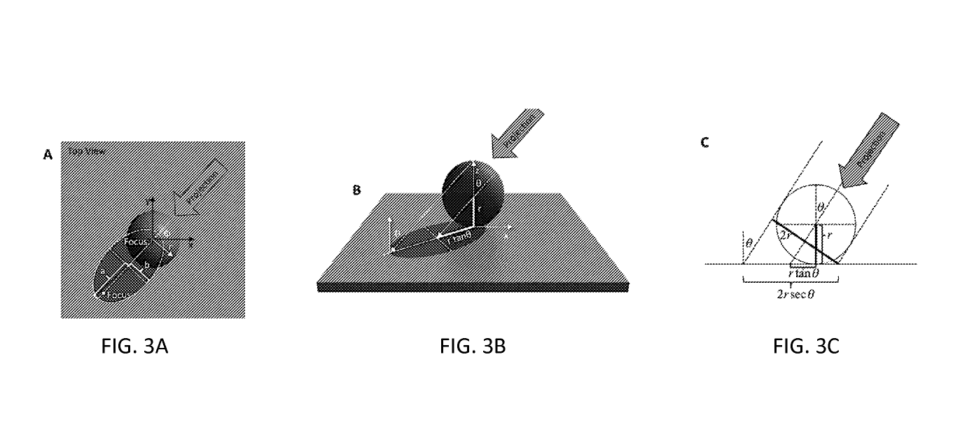

FIGS. 3A-C show an exemplary coordinate system, a single modeled sphere, and a projection surface, respectively, representing the substrate on which the shadows are cast that can be used by the model in generating the shadow structures. FIGS. 3A-B also shows a spherical polar coordinate reference system. The polar angle, φ, can be an angle of inclination from the z-axes and the azimuthal angle, φ, the rotation around the z-axis. Also shown are the trigonometric relations that govern the shape of the elliptical shadow for projection angles.

In some embodiments, the program can model an ideal directional source of deposition or etching as a parallel plane of light originating from infinite distance, and define the direction of deposition in a spherical coordinate system relative to selected axes of the colloidal crystal, for example, the crystal [001] and [100] axes of a hexagonally close packed monolayer of 1.5 μm diameter spheres.

In some embodiments, to simplify and accelerate the process by which shadow sphere lithography can be used to design metasurfaces, the program can assume that the incident sources comprise parallel rays. As a result of this assumption, the program can also assume that shadows produced by etched spheres are elliptical.

In some embodiments, a visual representation of a shadow shape comprises an image received by the program when a user selects a shadow shape from a menu of shadow cast shapes, for example, that have been preloaded into the program or that have been previously generated and saved by the user. When a user selects a shape, the program can load the particle and light casting parameters (e.g., pitch, gap, angles, etc.) associated with the fabrication of the shape. The shapes can be used alone and in combination to build a geometry for deposition onto a surface. Each of the shadow cast shapes can be simple shapes, e.g., approximating concave lenses, rectangles, parallelograms, interconnected lines, asymmetric bars, symmetric bars, triangular islands, or interconnected, honeycomb-like lattices, which can be combined to create more complex shapes.

In some embodiments, a user can alter the visual representation of the shadow shapes by dragging lines (e.g., legs of a shape, such as legs of a tripod). When a user drags a line, the program can adjust the parameters (e.g., pitch, gap, angles, etc.) of the shape corresponding to the changed line.

In some embodiments, a user can input a numerical representation of a shadow shape including particle and light casting parameters (e.g., pitch, gap, angles, etc.) and a visual representation of the resultant shadow shape is displayed. In some embodiments, the parameters can be input manually by the user. In other instances, a user can alter the particle and light casting parameters (and the corresponding shadow shape) by moving sliders or dials provided by the program. The sliders or dials can correspond to parameters (e.g., pitch, gap, angles, etc.) of the shape. For example, the position of a slider along an axis can correspond to a numeric value representing one of the parameters. In some embodiments, when the user moves a slider or dial, a displayed shape changes accordingly.

In some embodiments, the program is capable of defining one or more shadow shapes cast from different light/deposition sources. The shadow shapes from different sources can be displayed simultaneously to provide a visual representation of the final metastructure. The numerical representation of a shadow shape can therefore include one or more numbers a user enters to designate a number of active sources.

In some embodiments, a visual representation of the shadow shape comprises a color selected by a user. The color can correspond to at least one deposition source. Each deposition source can be distinguished by a different color. A user can also specify a color to designate a particular characteristic associated with a source (e.g., material type, etching duration, material thickness, etc.).

In some embodiments, the program enables a user to make continuous inputs or changes to a shape until a desired shape is shown. When a desired shape is shown, the program can output the corresponding parameters associated with the desired shape.

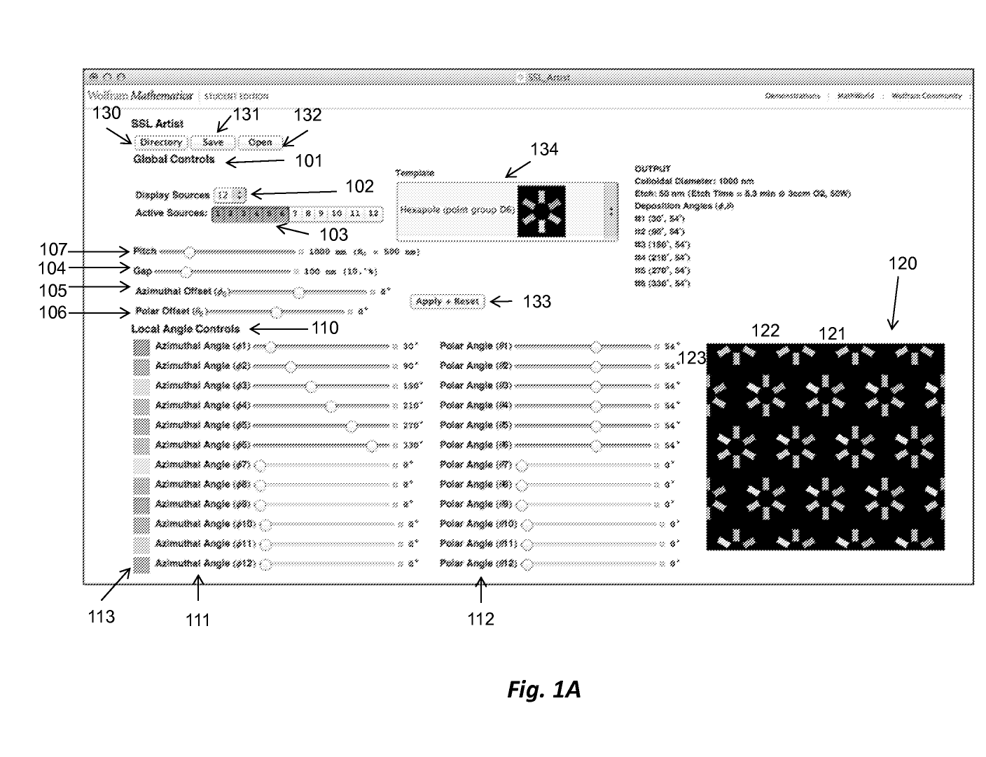

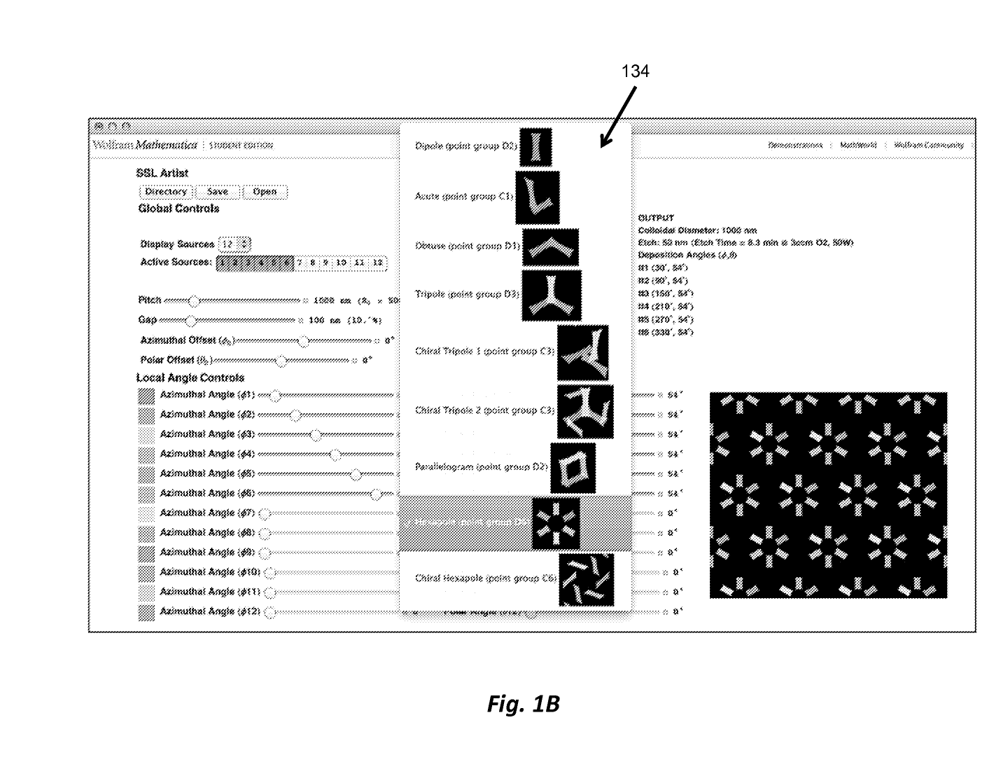

FIG. 1A shows one embodiment of a user interface for the computer-implemented design program.

The interface includes global controls 101, local controls 110, and an image corresponding to the global and local controls 120. Global controls apply to all deposition sources and local controls apply to a specific deposition source. The global control values and local control values are additive. For example, if there is a source that is set by a local control to be at 15° (e.g. polar angle) and another source set at 30°, and the global polar offset is 5°, then the shadows displayed for these two sources correspond to those produced with the sources are at 15° +5° =20° and 30° +5° =35°. The sources can be fixed relative to each other, with the same global offset added to each source. The interface also includes a directory 130, save function 131, open function 132, and apply and reset function 133.

The global controls include a control for the number of display sources 102. In some embodiments, the user can choose the number of display sources 102. Each display source can represent an independent angle of deposition. In some embodiments, the program can model the real-time design of shadow patterns from up to 12 independent angles of deposition.

The global controls include a switch to select which sources are active or inactive 103. The program can receive user-designated active sources among the number of display sources selected. For example, the user can select to have 12 display sources and only designate that sources 1, 2, 5, and 7 (or any other combination) are active.

The global controls include an adjustable gap control 104, an adjustable azimuthal offset control 105, an adjustable polar offset control 106, and an adjustable pitch control 107. As described in more detail below, the polar angle, φ, can be an angle of inclination from a crystal axis and the azimuthal angle, θ, measured counterclockwise from a crystal axis. The global azimuthal offset and polar offset controls can correspond to shifting all of the azimuthal and polar values the same amount in a certain direction (e.g. add 20 degrees to all values or subtract 20 degrees from all values). Gap can be the spacing or distance between neighboring particles used to generate the shadow shape. The global controls can also include an adjustable pitch control. Pitch is the center-to-center distance between neighboring particles used to generate the shadow shape. In some embodiments, the local controls 110 include adjustable azimuthal angles 111 for each of the active sources 103, and adjustable polar azimuthal angles 112 for each of the active sources 103. In some embodiments, each local control can affect a characteristic of one active source, while each global control can affect a characteristic of all active sources. Gap, pitch, azimuthal angle, and polar angle are four parameters that can correlate to the shape and size of the shadows that are created 120, and will be described in detail below in the discussion of FIG. 3.

In some embodiments, each set of azimuthal and polar values correspond to one leg in the shape displayed in 120. For example, in FIG. 1, Source 1 set at “Azimuthal Angle (φ1)”=30 degrees, and “Polar 1”=54 degrees corresponds to one leg of a hexapole 121. Source 2 set at “Azimuthal Angle (φ2)”=90 degrees, and “Polar 2”=54 degrees corresponds to a second leg of the hexapole 122. Source 3 set at “Azimuthal Angle (φ3)”=150 degrees, and “Polar 2”=54 degrees corresponds to a third leg of the hexapole 123, and so on.

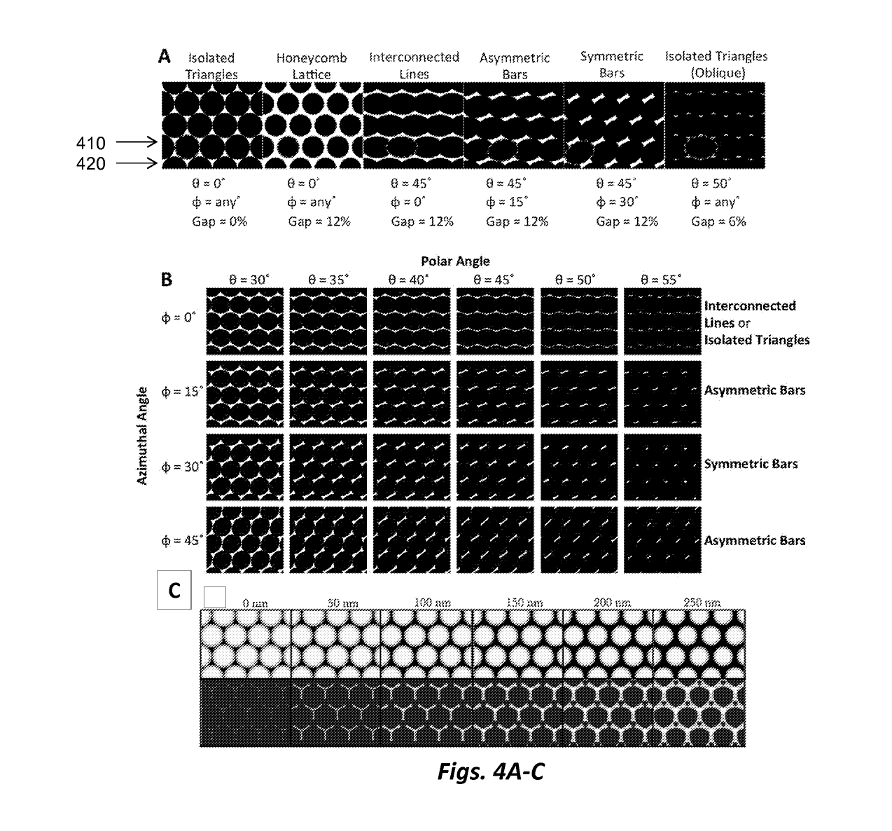

Changing the gap 104, pitch 107, azimuthal 105 111, and polar values 106 112 can result in changing the shapes in the image 120. Varying the orientation, size, and shape, of single lines and line segments can correspond to variations in a azimuthal or azimuthal angle of projection. A variation in a line or line segment's linewidth can correspond to a variation in the gap length. For example, in FIG. 1A, changing the values of Azimuthal 1, Azimuthal 2, or Azimuthal 3 correspond to changes in tripod leg 121, 122, and 123, respectively. In some embodiments, the program can receive changed values for Azimuthal 1, 2, and 3 either through detection of a movable visual controller (e.g., slider, dial, etc.) or through a received input of a numerical value. For example, in FIG. 1A the value for Azimuthal 1 can be adjusted lower either by sliding a circular indicator to the left or inputting a value less than “30” in the field to the right of the slider. In some embodiments, changing the values of Polar 1, Polar 2, or Polar 3 would correspond to changes in tripod leg 121, 122, and 123, respectively. In some embodiments, the program can receive changed values for Polar 1, 2, and 3 either through detection of a moved visual controller (e.g., slider, dial, etc.) or through a received input of a numerical value. In some embodiments, changing the gap length can affect the size of all three legs in a tripod, as described below in the description for FIG. 4(c).

In some embodiments, changing the size and location of the shapes in the image 120 can correspond to changes in the gap 104, pitch, azimuthal 105 111, and polar values 106 112. For example, if one leg of a tripod is dragged to a different location, dragged to a different size, or dragged into a different shape (using the visual controller), the corresponding gap, pitch, azimuthal and polar values would adjust to reflect changes made to the image. Alternatively, if the numerical values assigned to the gap 104, pitch, azimuthal 105 111, and polar values 106 112 are changed, the size and location of the shapes in the image 120 is correspondingly changed.

The local controls 110 include a control for distinguishing sources by assigning each source a color 113. Each color can correspond to a different source. The color chosen for each source can correspond to the color of a respective leg in the image 120. For example, if a user chooses red for Source 1 under the local controls, the leg corresponding to Source 1 in the image will also be red. The colors can also correspond to different materials. For example, red can correspond to Gold and orange can correspond to Silver. A user can choose a material from a directory of materials to assign to a color, or a user can input the material assigned to a color. A color can also represent the thickness of a material or etching time. A user can input the thickness of the material or the etching time the user chooses to associate with a given color.

In some embodiments, the program can also include a directory 130 where images are stored. In one embodiment, the images can be pre-generated and placed in a library linked to the program. The library can be accessed by a drop down menu 134. FIG. 1B shows an expanded view of a drop-down menu with templates. FIG. 1B shows what images may be found in a library of images associated with the program. In another embodiment, the images can be saved by a user 131 and included in a directory. Images can be accessed from the program by opening a file containing the images 132. When a user opens an image, the program can also load the corresponding global and local controls associated with the image.

In some embodiments, the program can also include an “apply and reset” control 133. This feature updates the “local” values with the sum of the current local value and current global offsets, and then resets the global offsets to zero. There is no change to the shape since this feature is only intended to make permanent any global changes that have been made.

FIG. 2B illustrates an exemplary complex design that can be obtained using the computer-assisted model described herein. The model uses three display sources, each capable of producing a different shadow shape indicated as Type 1, Type 2 and Type 3. Type 1 forms interconnected lines (see, FIG. 2C); Type 2forms asymmetric bars (see, FIG. 2D), while type 3 forms symmetric bars (see, FIG. 2E). To explore the parameter space, the following four free parameters in can be defined in FIG. 2B: (1) the “pitch”, or initial radius of the spheres, (2) the width of the “gap” opened between the spheres, (3) the azimuthal angle θ, and (4) the polar angles φ of the source relative to the monolayer colloidal crystal. Values for the polar angles φ and the azimuthal angle ƒ are assigned for each of these display sources. For a given pitch and gap value, the model can predict that the three sequential angles of deposition generate three qualitative types of features (that can be fabricated on a surface in a subsequent step): (1) an interconnected line, (2) an asymmetric bar, and (3) a symmetric bar. FIG. 2B illustrates an example of a complex pattern formed by combining multiple angles of deposition to overlay three types of features. Arrows in the lower expanded inset show the feature corresponding to the specific deposition source. Conversely, the computer-assisted model permits the user to assemble (or ‘draw’) the complex shape and provides the angles of deposition required to achieved the desired structure.

FIGS. 2C-H illustrate the correlation between the computer-generated image and a physical metastructure deposited using the parameters determined by the model. For a given gap and pitch value, deposition angles of varying polar angles φ can produce shapes that belong to a set of five phases: (1) interconnected lines, (2) asymmetric bars, (3) symmetric bars, (4) triangular islands, or (5) an interconnected, honeycomb-like lattice. Phases can be geometrical features from a single angle of deposition and can be continuous aside from the phase transitions. For example, setting Polar=0° produces a honeycomb lattice. As the polar angle starts deviating from 0°, the shadows of the honeycomb pattern become more distorted. Eventually, as the polar angle increases, the pattern transitions into either interconnected lines or symmetric or antisymmetric bars, depending on the azimuthal angle. As the polar angle is continually increased further, the features break apart even further and form triangular islands. Finally, once the polar angle is increased too far, the spheres block all the substrate, and there is only shade. Because the features can be broken into 5 types of shapes, and the morphology of these shapes changes continuously with angle, each of the shapes can correspond to a “phase”.

FIGS. 2C-E show examples of these phases and illustrates how the features each repeat at θ=60° intervals due to the six-fold rotation symmetry imposed by the hexagonal lattice. FIGS. 2F-H show experimentally realized samples that demonstrate the overlay of these theoretically predicted phases.

Typically, varying the azimuthal angle θ produces continuous transitions between the different phases of shadows offering many intermediate positions and shapes, while varying the polar angle φ or the gap between the spheres, controls position, length, and width of each of these features.

FIGS. 4A-C show a representative group of features that demonstrate the ability to tune the orientation, size, and shape, of single lines and line segments, by variation of a azimuthal or azimuthal angle of projection. Dark sections 410 represent the areas in the shadow of the modeled light source, while light sections 420 represent areas exposed to the light source and correspond to areas of deposition when fabricating a structured surface. The linewidth can also be tuned through variation of the nearest-neighbor gap length. In some embodiments, there are three free parameters in the model: two angles and gap length. FIG. 4A shows the five (qualitative) phases that occur within the parameter space of shadows: i) isolated triangles, ii) honeycomb lattice, iii) interconnected lines, iv) antisymmetric bars, and iv) symmetric bars. A lattice of triangles is formed at normal incidence with no gap (no etching, spheres are close-packed). A honeycomb lattice is formed at normal incidence for finite gap (some etching). The interesting isolated structures tend to appear, in general, at intermediate polar angles (θ=30°−60°). Within this regime, interconnected lines are formed for azimuthal angles near φ≈0°+n·60°, asymmetric bars for angles near φ≈15°+n·30°, and symmetric bars only at angles φ=30°+n·60°, where n ε integers.

FIG. 4B shows how as the azimuthal angle φ is swept at constant θ, the features transition smoothly from lines to asymmetric bars, to symmetric bars and back again. Eventually as the polar angle θ is increased further to oblique angles, the interconnected line phase breaks apart into isolated, oblique triangles. Beyond θ˜65°, the spheres tend to obscure the entire substrate (in some embodiments, this is not counted as a phase). The exact angles at which different phases transition from one to another depend on the ratio between the gap g between spheres and the pitch p of the array (g/p). The length and width of each feature is controlled by varying the gap size and θ. Although both of these parameters affect the length/width, the gap is more closely linked to the overall width of features and the angle θ more closely linked to the length of each feature.

As discussed above, shadow shapes can be combined to create complex designs. FIG. 4C shows three overlapping line segments (corresponding to three display sources, each of which have its unique angle of deposition) that form a tripod structure. In some embodiments, each leg of a structure can comprise a different material. Individual lines or line segments can be overlapped to build up complex shadows, step-by-step, by adding multiple light sources, at different angles, to the model. For example, by exploiting the crystal symmetry, it is possible to generate tripod structures.

In some embodiments, the width of projected tripods can be tuned in the program by adjusting the gap control 104. FIG. 4C shows the dependence of the feature width of projected tripods on the gap distance between the nearest neighboring spheres and shows the different tripod sizes at different gap widths. As discussed above, the program can receive changed values for gap control either through detection of a moved visual controller (e.g., slider, dial, etc.) or through a received input of a numerical value.

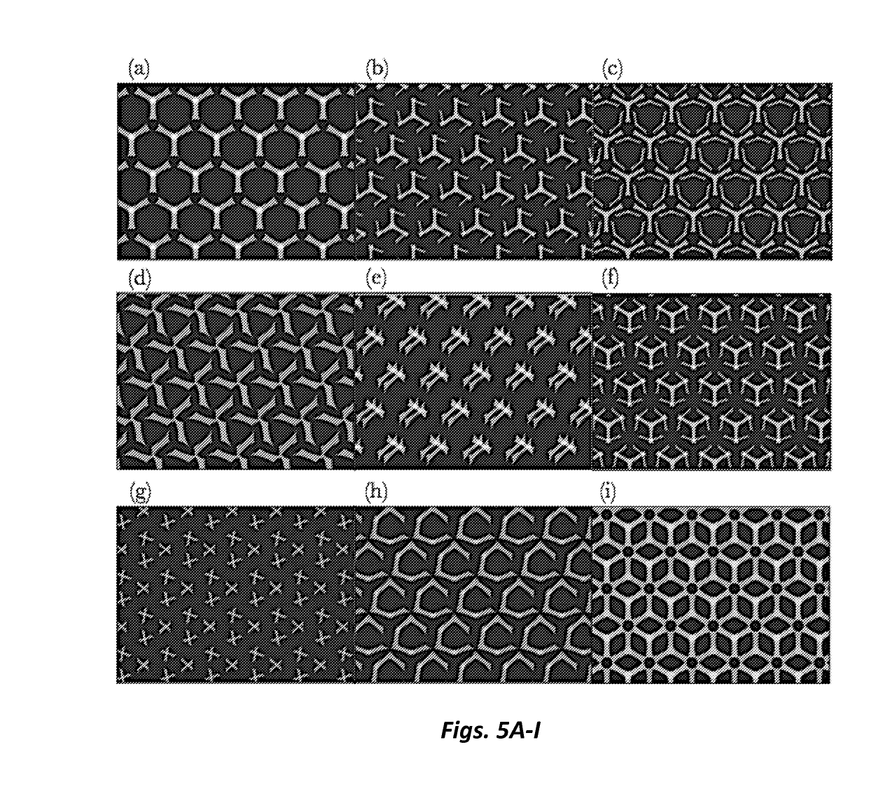

FIG. 5 shows a sample of shapes that demonstrate the variety of simple structures that can be built-up with the program. Azimuthal angles in the range of φ=30°−60°, and a wide range of azimuthal angles are shown to achieve these shapes. Different colors of projected light can be used to represent separate deposition sources and to suggest where multiple materials may be used in the device design. For example, each tripod leg 510, 520, 530 in FIG. 5(a) are generated using a different light/deposition source and each can be of a different color associated with its source.

FIGS. 5(b), (c), and (f) show tripods with various extra features that can help tune the resonance and improve coupling between the structures. These more complex structures are generated using a model includes six light/deposition sources. For example, in FIG. 5(b) the extra features add chirality to the tripod so that it may couple strongly to light with circular polarization. In FIG. 5(c), the extra dipole-like features close to the gaps between adjacent tripoles may introduce an extra resonance peak and also aid in electromagnetically coupling the tripoles together. This coupling may make the optical peaks broaden and possibly overlap, leading to a widening of the resonant peaks. In FIG. 5(f), the tripods are loaded with extra features that add a new resonance frequency response to the spectrum and may also strongly shift the resonance of the tripoles to longer wavelengths. FIG. 5(d) shows a pinwheel structure (three sources). FIG. 5(e) shows isolated transistor-like structures (three sources). FIG. 5(g) shows an “X” geometry (six sources). FIG. 5(h) shows Split-Ring resonators composed of isolated line segments (five sources). FIG. 5(i) shows interpenetrating tripod arrays (six sources).

The shape of a nanoantenna can affect the frequency dependence of the amplitude-, polarization-, and phase-response of the nanoantenna to incident light. For example, a tripod (e.g., FIG. 5(a)) is polarization insensitive. A pinwheel (e.g., FIG. 5(d)) is similar, but slightly chiral, so it interacts with circular polarization. A tripod with extra legs can either make it strongly chiral (e.g., FIG. 5(b)), or can significantly change the frequency response (e.g., FIG. 5(c), FIG. 5(f)) by increasing the electromagnetic coupling between nearest neighbors. A “C” (e.g., FIG. 5(h)) couples to the magnetic component light and is one of the most popular designs for a metasurface nanoantenna. A transistor structure (e.g., FIG. 5(e)) can be useful for biosensing. The other structures (e.g., FIG. 5(g), (i)) can give more complicated responses that may yield multiple spectral (e.g. transmission, reflection, absorption) peaks of different intensities. These peaks may be sharp in some cases, or wide in others. Depending on the application (for example identification of a biomolecule with a particular optical resonance) one or another pattern may be selected that gives a spectral peak, trough, or slope that enables the strongest interaction with the molecule.

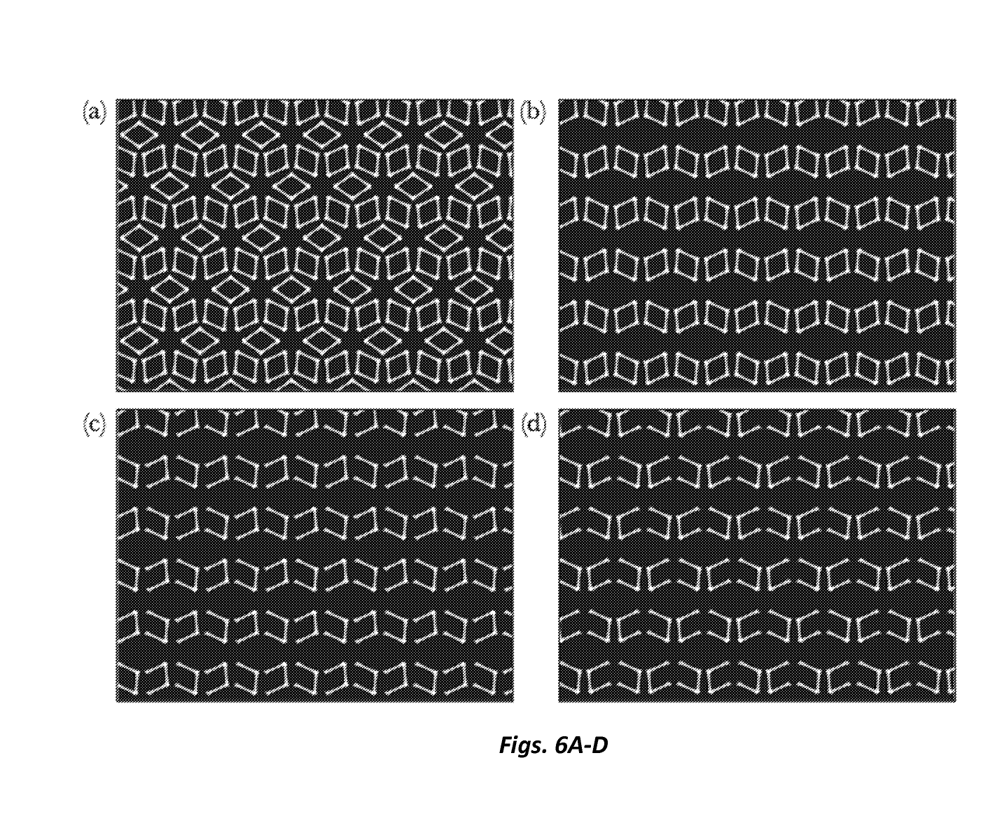

FIG. 6 shows a sample of parallelogram-based shapes generated from hexagonal symmetries. Adding or subtracting particular line segments, as shown, may significantly alter the function (e.g. optical response) of these structures. Each line segment in a unit cell can represent a separate deposition step.

FIG. 6(a) shows an array consisting of three types of parallelograms (twelve sources). FIG. 6(b) shows four sources removed to generate an array with only two types of parallelograms (eight sources). FIG. 6(c) shows antisymmetric variations with two more sources removed (six sources). FIG. 6(d) shows symmetric variations with two more sources removed (six sources).

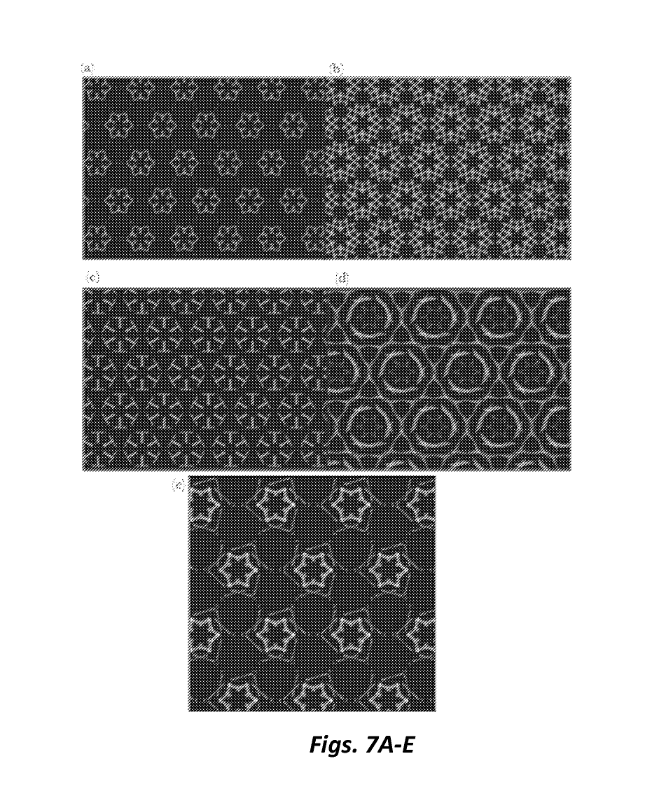

FIG. 7 shows a small sample of possible complex geometries using 10-24 different azimuthal angles and up to three different azimuthal angles. The use of many angles of deposition can create far more intricate patterns, and using multiple azimuthal angles, φ, can give rise to nested structures.

FIG. 7(a) shows snowflakes connected with dotted traces. FIG. 7(b) shows a cross-hatched hexagon. FIG. 7(b) can display a Fano Resonance, a type of resonant scattering phenomenon that gives rise to an asymmetric line-shape, which has a sharply asymmetric frequency response. This can be interesting for biosensing where the slight shifts of the position of the peaks due to presence or absence of the detected molecules can significantly change the amount of transmitted light. FIG. 7(c) shows snowflakes with end-caps. FIG. 7(d) shows three levels of nested structures: a star within a circle within a series of interconnected lines. FIG. 7(e) shows a double nested star configuration.

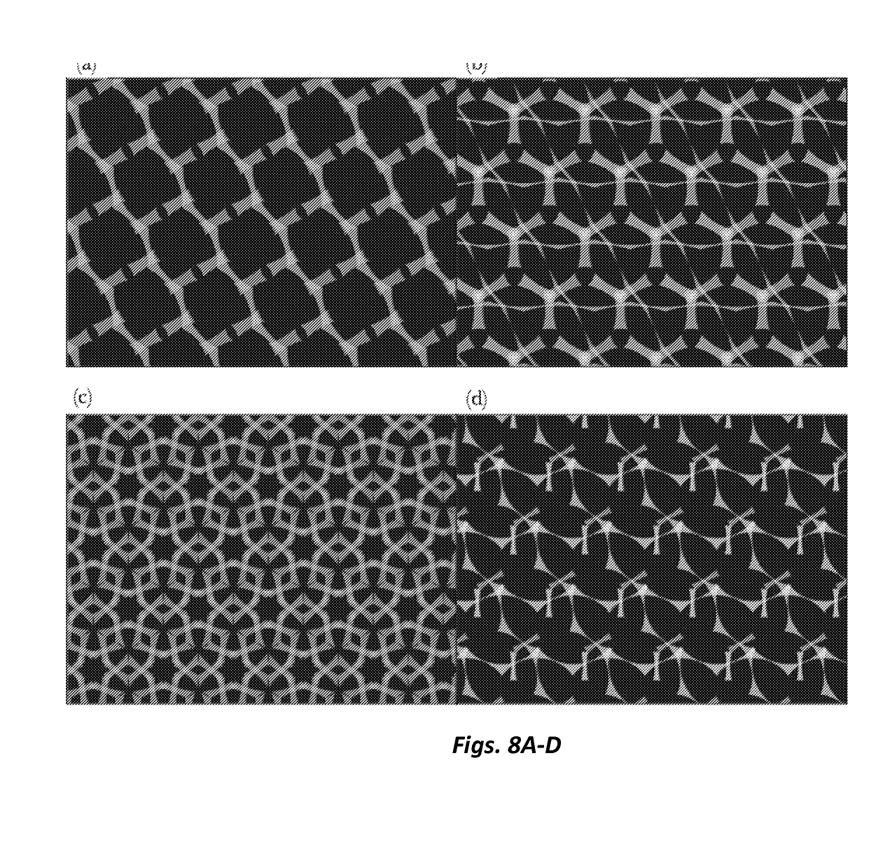

FIG. 8 shows a small sample of possible interconnected designs. In some embodiments, it may be possible to use the program described herein to make addressable devices, active sensors, and optical elements. For example, nano-antennas can be coupled in unique ways and tripod arrays or junctions can be individually addressed. Once isolated features have been designed they can be interconnected with any of the six orientations of uninterrupted lines (e.g., as shown in FIG. 3(c)). FIG. 8(a) shows interconnected nano-antennas. FIG. 8(b) shows addressable tripod arrays. FIG. 8(c) shows complex overlapping rings. FIG. 8(d) shows addressable junctions.

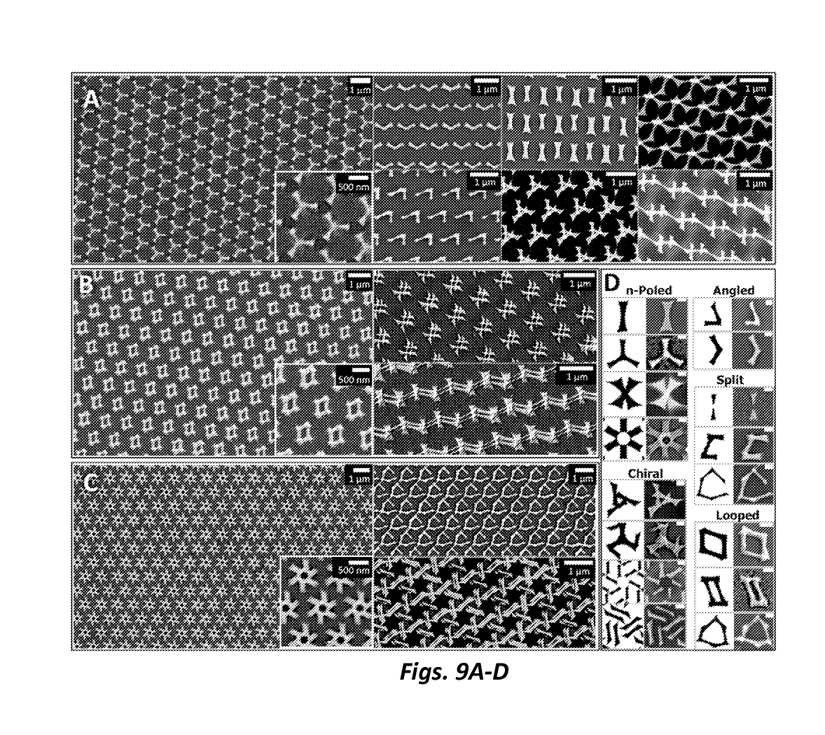

FIG. 9 shows scanning electron microscope (SEM) images of various metasurfaces designed and fabricated using shadow sphere lithography. In some embodiments, once a design is finalized, the program outputs parameters (e.g., pitch, gap and angles) that can be used in fabrication. Fabrication of the results outputted by the program verified the program's results.

FIG. 9A shows examples of metasurfaces fabricated by composing two to three different angles of deposition. FIG. 9B shows devices formed by three to four angles of deposition. FIG. 9C shows devices formed by five to six different angles of deposition. FIG. 9D shows a subset of possible unit cells categorized according to optical function. In some embodiments, unit cells can be categorized according to optical function (e.g., connected n-poles, angled resonators, chiral resonators, split dipoles, and split-ring resonators, and loop antennas). The unit cells can be predicted and generated by the program and fabricated by shadow sphere lithography.

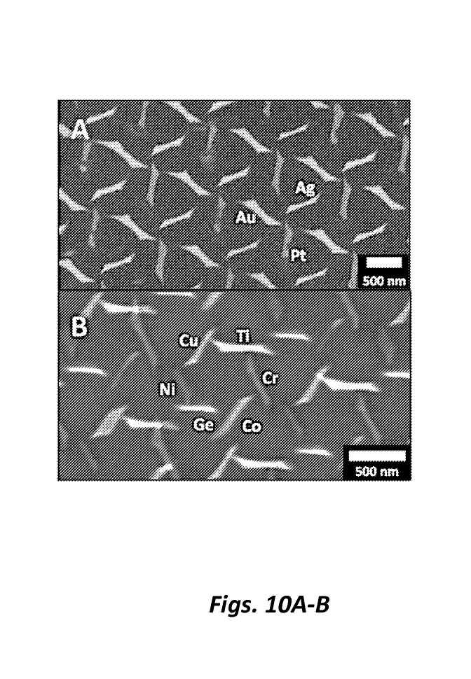

FIG. 10 shows SEM images of tripolar and hexagonal structures. FIG. 10A shows an array of chiral, tripolar structures (formed by three asymmetric bars) fabricated with each bar composed of Au, Ag, and Pt. FIG. 10B shows an array of chiral, hexagonal structures (formed by six asymmetric bars) fabricated with each bar composed of Cu, Ti, Cr, Co, Ge, or Ni. In some embodiments, 2 nm of Ti can be deposited under the Au bar to increase adhesion of the Au to the substrate, and 2 nm of Ge under the Ag bar to improve quality of the Ag film. Au can be used because it is not chemically reactive and does not corrode. This characteristic, however, means it does not adhere well to most materials. For a gold film to stay on a substrate, the first layer must comprise a material that can adhere to gold. Ti is sometimes used. Ag, on the other-hand, sticks to the substrate (e.g., silicon wafers or glass), but for films less than 100 nm thick, tends to fracture and separate into discrete islands and does not remain smooth until it is thick enough. A thin layer of Ge prevents the Ag from becoming granulated and promotes smooth, continuous films that are advantageous for making nanoantennas.

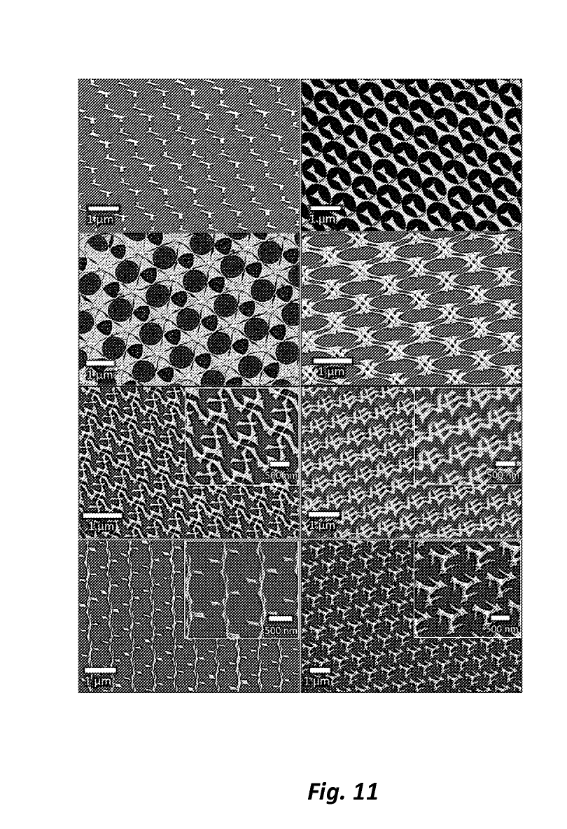

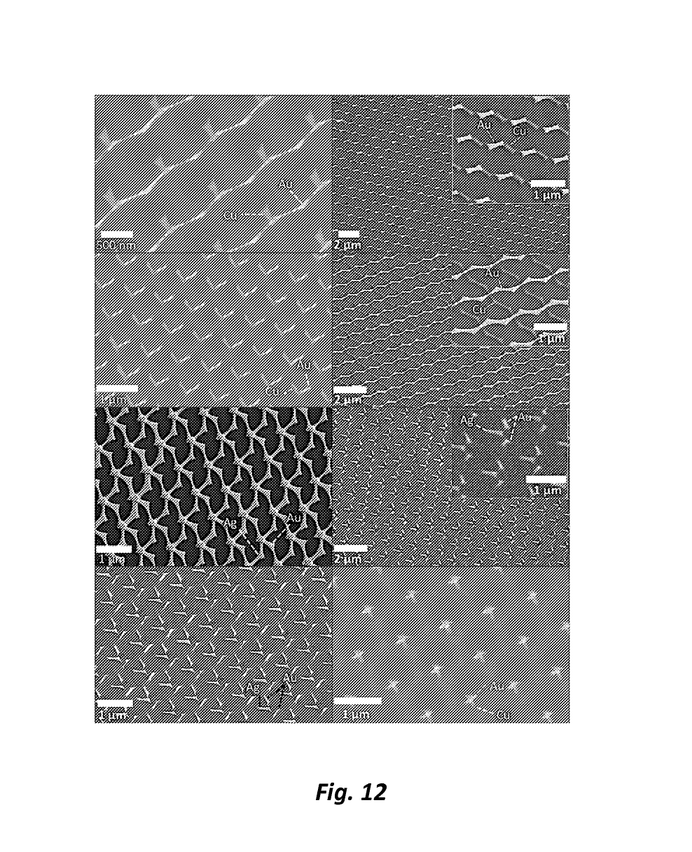

FIG. 11 shows eight different metasurfaces fabricated with 2-6 angles of deposition, fabricated from Ag on a Ge nucleation layer.

FIG. 12 depicts eight different metasurfaces fabricated from multiple materials, including Ag, Au, and Cu.

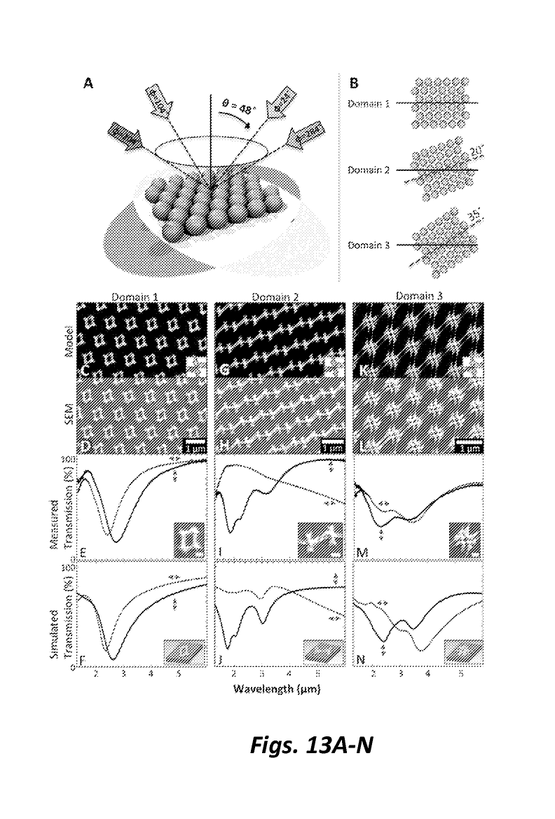

FIG. 13A shows a 3-D scheme for a four-sided “looped” array of nanoantennas. 2 nm of Ti (as an adhesion layer) were deposited followed by 20 nm of Au at φ=48° and θ={18°, 98°, 198°, 278°} on a borosilicate substrate.

FIG. 13B shows the orientation (relative to the initial design) of three domains on the same substrate. Domain 1 is oriented along the same axis as the initial design. Domain 2 is oriented at 20 degrees relative to the axis of the original design. Domain 3 is oriented at 35 degrees relative to the axis of the original design.

FIG. 13C shows the designed structure rendered by optical ray tracing. The sphere sizes and positions, and the angles of projection were inputted into a ray-tracing software (e.g., POVray) to render 3D images.

FIG. 13D shows an SEM image of the fabricated sample. FIG. 13E shows the corresponding FTIR and FIG. 13F shows the simulated spectra.

FIGS. 13G-N show modeled, imaged, characterized, and simulated data correspond to two other randomly oriented domains on the same substrate. FIGS. 13G-J show an SEM image of the fabricated sample, a corresponding FTIR and a simulated spectra, respectively, for Domain 2. FIGS. 13K-N show an SEM image of the fabricated sample, a corresponding FTIR and a simulated spectra, respectively, for Domain 3.

In some embodiments, Au can form an optically active layer, as a Ti adhesion layer can be too thin to significantly affect the optical spectra, while a common microscope cover-slip (borosilicate glass) can offer a substrate suitable optical transmission window between 0.4 um-6 um.

In some embodiments, an overlap of shadow-defined features, as well as the gradual narrowing of the gaps between the spheres due to the build-up of deposited material, can produce a 3D topology that is not physically represented by a flat, simulated model. Even in those cases, it is possible to match the simulated spectra to the experimental spectra by approximating an “effective thickness.” This outcome indicates that even a possibly complex 3D topology of shadow sphere lithography-defined structures serves only to slightly red-shift the entire spectrum, an effect that can be easily predicted by calibrating a single parameter (e.g., the thickness).

The subject matter described herein can be implemented in digital electronic circuitry, or in computer software, firmware, or hardware, including the structural means disclosed in this specification and structural equivalents thereof, or in combinations of them. The subject matter described herein can be implemented as one or more computer program products, such as one or more computer programs tangibly embodied in an information carrier (e.g., in a machine readable storage device), or embodied in a propagated signal, for execution by, or to control the operation of, data processing apparatus (e.g., a programmable processor, a computer, or multiple computers). A computer program (also known as a program, software, software application, or code) can be written in any form of programming language, including compiled or interpreted languages, and it can be deployed in any form, including as a standalone program or as a module, component, subroutine, or other unit suitable for use in a computing environment. A computer program does not necessarily correspond to a file. A program can be stored in a portion of a file that holds other programs or data, in a single file dedicated to the program in question, or in multiple coordinated files (e.g., files that store one or more modules, sub programs, or portions of code). A computer program can be deployed to be executed on one computer or on multiple computers at one site or distributed across multiple sites and interconnected by a communication network.

The processes and logic flows described in this specification, including the method steps of the subject matter described herein, can be performed by one or more programmable processors executing one or more computer programs to perform functions of the subject matter described herein by operating on input data and generating output. The processes and logic flows can also be performed by, and apparatus of the subject matter described herein can be implemented as, special purpose logic circuitry, e.g., an FPGA (field programmable gate array) or an ASIC (application specific integrated circuit).

Processors suitable for the execution of a computer program include, by way of example, both general and special purpose microprocessors, and any one or more processor of any kind of digital computer. Generally, a processor will receive instructions and data from a read only memory or a random access memory or both. The essential elements of a computer are a processor for executing instructions and one or more memory devices for storing instructions and data. Generally, a computer will also include, or be operatively coupled to receive data from or transfer data to, or both, one or more mass storage devices for storing data, e.g., magnetic, magneto optical disks, or optical disks. Information carriers suitable for embodying computer program instructions and data include all forms of nonvolatile memory, including by way of example semiconductor memory devices, (e.g., EPROM, EEPROM, and flash memory devices); magnetic disks, (e.g., internal hard disks or removable disks); magneto optical disks; and optical disks (e.g., CD and DVD disks). The processor and the memory can be supplemented by, or incorporated in, special purpose logic circuitry.

To provide for interaction with a user, the subject matter described herein can be implemented on a computer having a display device, e.g., a CRT (cathode ray tube) or LCD (liquid crystal display) monitor, for displaying information to the user and a keyboard and a pointing device, (e.g., a mouse or a trackball), by which the user can provide input to the computer. Other kinds of devices can be used to provide for interaction with a user as well. For example, feedback provided to the user can be any form of sensory feedback, (e.g., visual feedback, auditory feedback, or tactile feedback), and input from the user can be received in any form, including acoustic, speech, or tactile input.

The subject matter described herein can be implemented in a computing system that includes a back end component (e.g., a data server), a middleware component (e.g., an application server), or a front end component (e.g., a client computer having a graphical user interface or a web browser through which a user can interact with an implementation of the subject matter described herein), or any combination of such back end, middleware, and front end components. The components of the system can be interconnected by any form or medium of digital data communication, e.g., a communication network. Examples of communication networks include a local area network (“LAN”) and a wide area network (“WAN”), e.g., the Internet.

### Fabrication

The computer-implemented program described herein above, can enable the design of a device in minutes. The ability to control the orientation of a rotation-stage through a feed-through in an electron beam evaporator can enable the creation of most devices (including those that required multiple, spatially separated materials) during a single pump-down of the PVD vacuum chamber, and typically in under 2 hours. With further development of the quality and size of single-domain monolayer colloidal crystal, this technique may possibly be scaled-up even large area (wafer-scale) devices. The close match between modeled and fabricated structures indicates that a computer-generated model and an appropriate set of design rules can be used to predict new structures that are guaranteed to be fabricable.

In one embodiment, fabrication involves taking MCCs composed of polystyrene spheres with 1 μm diameter at an air/water interface, depositing them on bare, silicon wafers, and performing an isotropic etch with oxygen plasma to reduce the diameters of the spheres and open the gaps specified by our designs. The samples can be mounted onto a custom-built, 2-axis rotation stage. The relative angle can be adjusted between the sample, and source of deposition, for each angle of deposition, as specified by the output of the program.

In one instance, polystyrene (PS) microspheres were obtained from Polysciences (Warrington, Pa.) with 0.99 μm diameter as 2.6% (wt.) latex suspensions. To obtain high quality monolayers, the PS beads suspensions were purified extensively before use by diluting the latex suspensions by 50% in ethanol and centrifuging them at 3000 rpm for 30 minutes. The supernatant was then discarded and the pellet of beads was re-suspended in a 1:1 mixture of ethanol in water. This process was repeated at least 3 times. To prepare the self-assembled MCCs, disposable, polystyrene petri dishes (150×25 mm, Beckton-Dickinson) were filled with a 17 μM aqueous solution of NaOH. A glass slide (made hydrophilic by treatment with air plasma for 5 minutes) was inserted at a 30° angle between the glass slide and the water meniscus. The suspension was slowly added to the glass slide, leading to the insertion of the PS microspheres at the air-water interface. The microspheres remained trapped at the air-water interface and assembled into polycrystalline MCCs within minutes. To pick-up the MCCs, the receiving substrates (typically silicon or glass) were inserted underneath the monolayer surface and pulled out of the water at a shallow angle. The samples were dried in ambient conditions at a 45° angle with respect to the vertical direction.

50-120 nm gaps were generated (depending on the output of the design software) between the spheres by exposing samples for 8-12 minutes to an O₂ plasma etch (Micro-stripper 220, Technics) at 50W RF power and 3 sccm O₂ gas flow.

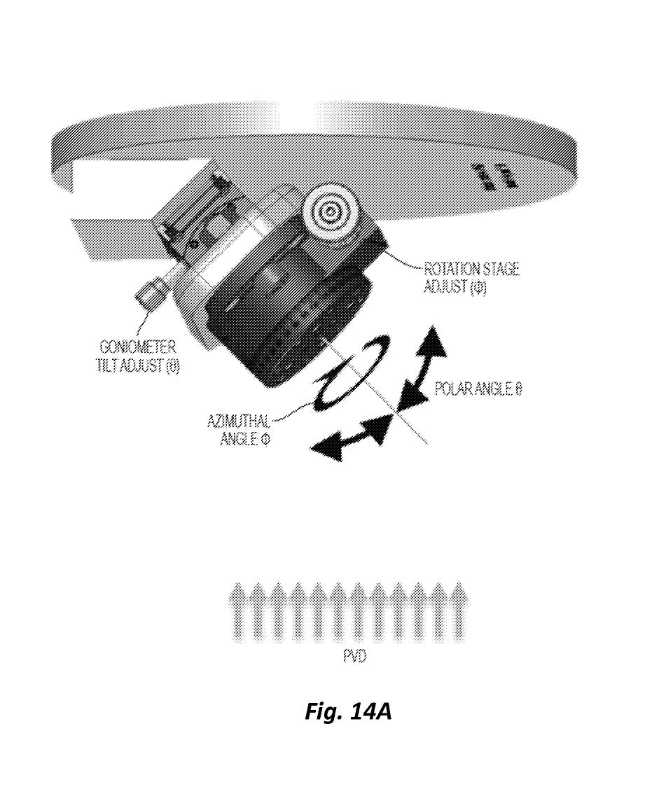

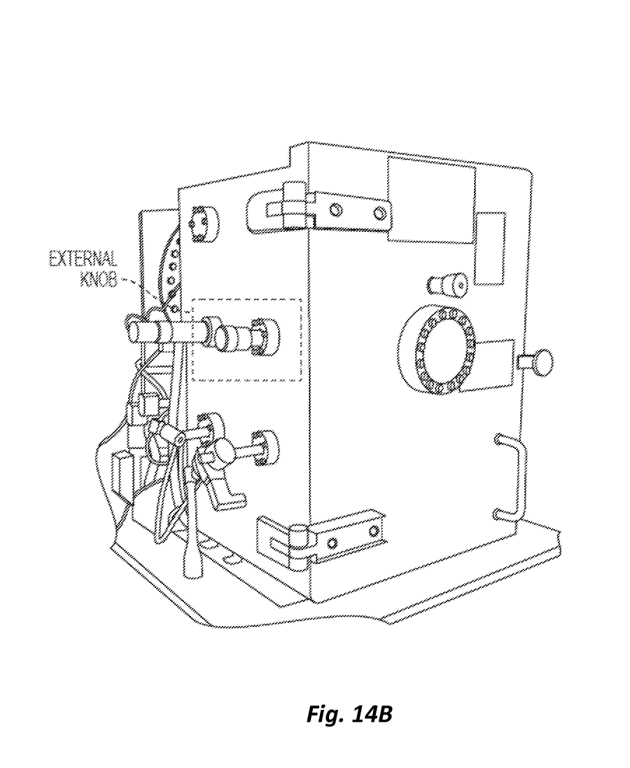

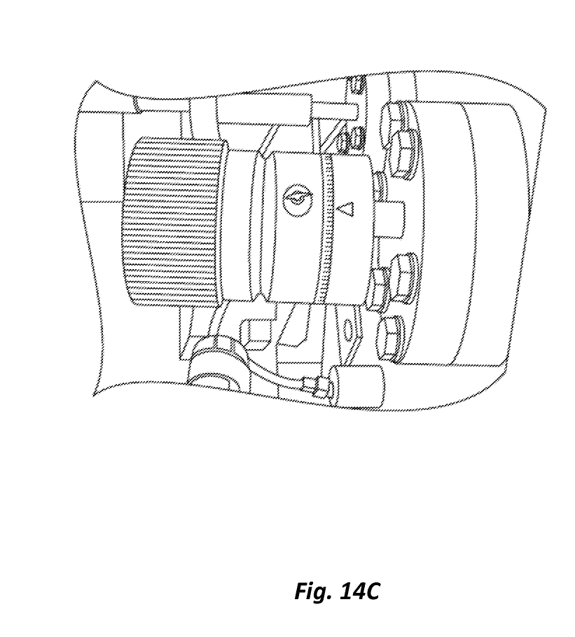

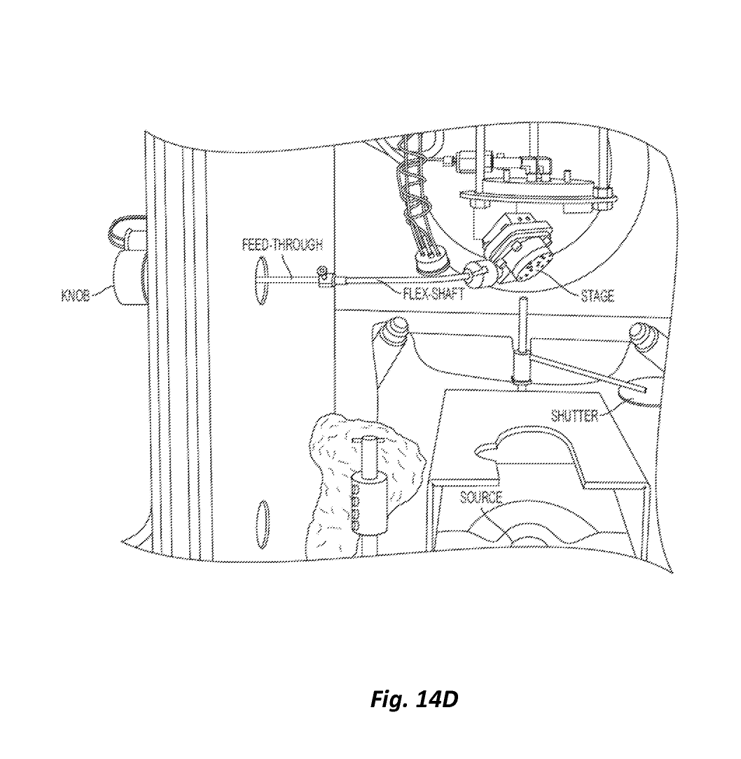

FIG. 14A shows a vacuum-compatible sample rotation stage with two, independently controlled rotation axes consisting of i) an aluminum rotation stage (CR-1 custom, Thorlabs) with continuous 360° rotation and 0.2° resolution, to control the azimuthal angle, and ii) a stainless steel rotation stage (GOHS-40A35, OptoSigma Corp.) with ±20° range and 0.2° resolution mounted at 45° to the sample/source axis, to control the polar angle. The sample stage was assembled with a set of custom-built aluminum components, and vented stainless-steel screws (McMaster). FIG. 14B shows an electron beam deposition system including an external knob. FIG. 14C shows an expanded view of the external knob on the electron beam deposition that may be used to adjust the orientation of the sample rotation stage inside the vacuum chamber. FIG. 14D shows a knob, feed through, flex shaft, rotation stage, shutter, and source. The stage was mounted in an electron beam evaporator (Sharon) and an external knob connected to a manual feed-through and a flexible shaft (McMaster) was used to precisely (±0.5°) control the azimuthal angle of the sample relative to the source.

In all cases in which Ag was used, the devices were fabricated by first sequentially depositing a nucleation layer (2 nm of Ge at 1 Å/s) at each angle required from the specified design, and then sequentially depositing the active layer (20 nm of Ag at 1 Å/s) on top of the nucleation layer at each angle required by the design. At the completion of each deposition step (a single deposition at a single angle), the source shutter (while maintaining a constant deposition rate) was closed, the angular control knobs were adjusted to the next angle, and the shutter was opened to continue deposition onto the sample. For devices composed of Au, the same procedure was performed with Ti as the adhesion layer and then Au as the active layer. In each case, after deposition, the polystyrene monolayer was removed with an adhesive tape (e.g., Scotch-tape).

In some embodiments, the output of the program can output parameters to the fabrication tools in the following way:

(1) To set the pitch of the lattice, the pitch output from the program can correspond to forming a monolayer of spheres of a certain diameter.
(2) To set the gap, the program can send instructions to a plasma etching system to etch the spheres for the amount of time equivalent to the one half the gap size (e.g., the amount by which the radius of the spheres is reduced relative to the initial radius). Etching is linear in time, so once the etcher is calibrated, and the etch rate is known (e.g., 10 nm/minute), the plasma etcher can be activated for the appropriate length of time. For a plasma etching system that is networked, the computer can send these parameters (gas flow rate, RF power, length of etch) directly to the etcher. The user can load the sample and start the process manually.
(3) To set the angles of the sources, the program can send the angles to a motorized rotation stage installed in the deposition system. The system begins depositing at the first angle, and after the desired film thickness is reached the program can instruct the rotation stage to move to the next angle of deposition. In some embodiments, there are motors that are controlled by voltage. For example, sending a voltage from 0-5 determines the speed of rotation. With proper calibration, sending a specific voltage for a specific length of time can adjust the stage to a specific angle. In some embodiments, a computer with the shadow-design software can be connected to a digital-to-analog converter (DAC) and, over USB, have the software dictate the voltage and length of time to drive the motor to reach the desired angle. In some embodiments, the motors can be controlled directly by USB.
(4) Depending on the desired materials for each deposition (e.g., Gold, Silver, Platinum, etc.) the program can also indicate which material to choose for each angle. In some embodiments, the program can control over a network connection the choice of material and deposition rate/duration during the fabrication process

One of the strengths of shadow sphere lithography is the simplicity with which multiple materials can be incorporated within the metasurface without ever removing the sample from the PVD chamber. This characteristic can eliminate the need for extra steps involving further lithography or registration, and greatly speeds up and simplifies the realization of complex devices.

Any material that can be deposited by PVD can be used in shadow sphere lithography; each line segment in a design can correspond to a different material (or thickness). FIG. 13 shows this capability in the form of two fabricated patterns that incorporated combinations of three to six different metals.

### Shadow Sphere Lithography With Nonperiodic Structures

In some embodiments, shadow sphere lithography includes template encoded shadow sphere lithography (TESSL). TESSL expands the quality and range of structures accessible to SSL. In TESSL, a patterned template can be used to direct the self-assembly of micro- and nanospheres into large area (cm²), well-defined, high-quality arrays with periodic, quasiperiodic, or aperiodic order. These spheres can then be transferred to opaque, transparent, or flexible substrates, and shadow deposition can be performed to define a broad spectrum of metasurfaces. TESSL can be used to fabricate many different kinds of metasurfaces, including (i) a periodic metasurface, based on a simple unit cells, (ii) a quasicrystalline metasurface, such as one based on a Penrose tiling, and (iii) and an aperiodic metasurface, such as one based on a Fermat spiral. To predict the patterns formed by TESSL, two techniques can be used: one that models shadows as ellipses, and the other that uses ray tracing. The techniques described herein allow for colloidal quasicrystal formation by template-directed self-assembly, and shadow deposition through spheres that are arranged non-hexagonally.

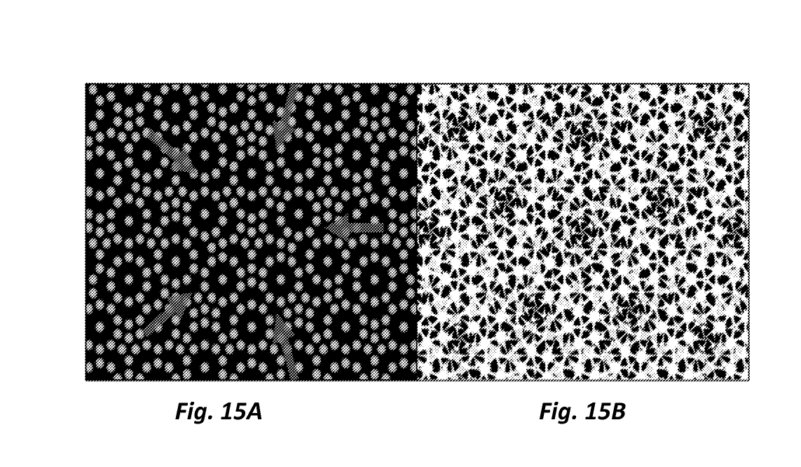

FIGS. 15A-B show a Penrose tiling of spheres and the corresponding projected pattern of shadows, according to some embodiments of the present disclosure.

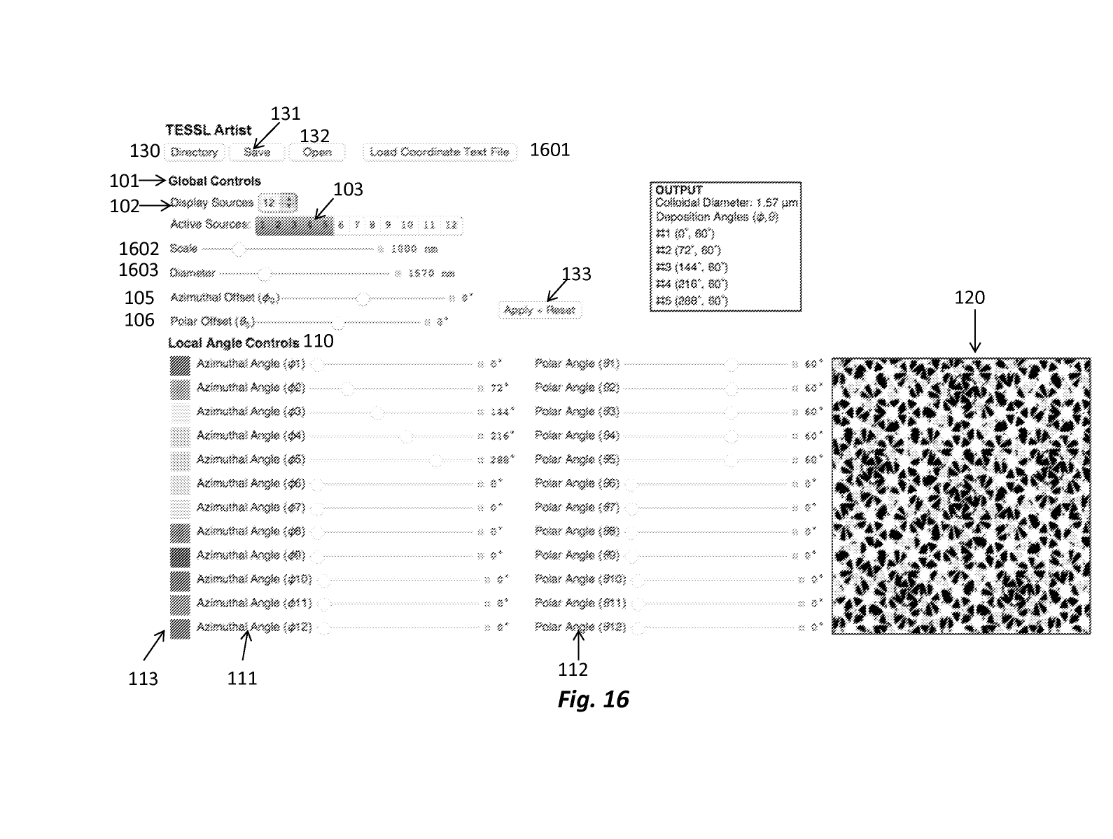

In some embodiments, modeling shadows for large-area complex patterns can involve a multi-step process. First, coordinates of the spheres in large-area complex patterns, such as Penrose tilings or Fermat spirals, are calculated (e.g., in Mathematica). A Penrose tiling is a non-periodic lattice generated by an aperiodic set of prototiles. A Penrose tiling is a quasicrystal. Quasicrystals are structures that have rotation but not translation symmetry. This property enables Quasicrystalline metasurfaces to have optical transmission properties that are independent of the angle between the incident light and the metasurface, and that display a high degree of rotational symmetry. These properties are highly desirable for many applications such as creating perfect absorbers and aberration-free ultrathin flat lenses. Next, the coordinates are imported into software optimized for ray tracing (e.g., MegaPOV). As described in more detail in FIG. 16, virtual spheres are placed at the coordinates, and shadows are simulated in physical vapor depositions (PVD) as shadows in virtual sources of light. FIG. 15A shows an example of a Penrose-tiling of spheres, and FIG. 15B shows an example of a shadow pattern that can be formed using five angles of deposition.

FIG. 16 shows a screenshot of an embodiment of a shadow sphere lithography design program. FIG. 16 shows many of the same elements as described in FIG. 1A. In addition, FIG. 16 shows a coordinate input 1601, scale 1602 and diameter 1603.

Similar to the template input 134 in FIG. 1A, a coordinate input 1601 can also generate a corresponding image 120 that changes based on changes in the global and local controls. As described above, virtual spheres can be placed at particular coordinates, and shadows simulated based on the spheres' coordinates. The coordinate input 1601 can comprise a text filed containing [x, y] coordinates defining the position of the spheres. The series of [x, y] coordinates can define any shape. In some embodiments, the shape comprises a random assembly of spheres manually chosen by a user. In some embodiments, the shape defines a periodic, non-periodic, or quasi-periodic geometry. In some embodiments, a user can generate coordinates using an external program (e.g., Mathematica or MATLAB) and export them as a CSV test file. This file can then be imported and received as a coordinate input to the design program. As discussed above, there are an infinite number of possible lattices, and a user is free to choose any manner in which to generate coordinates. For example, there are publicly available scripts for generating various Penrose tilings and spiral structures. A user can also create an original script for generating a structure.

Scale 1602 refers to a scaling factor that can be applied to a set of coordinates. For example, scale 1602 applies a factor to all [x, y] coordinates in a coordinate input 1601 reducing or increasing the distance between the spheres proportionally by the same factor. Diameter 1603 refers to a size of the particle. The distance or gap between the surfaces of the spheres is proportional to the diameter of the sphere. For example, the smaller the diameter of the sphere, the greater the distance or gap between the spheres.

In some embodiments, the graphical user interfaces illustrated in FIGS. 1A and 16 can be combined into a single interface.

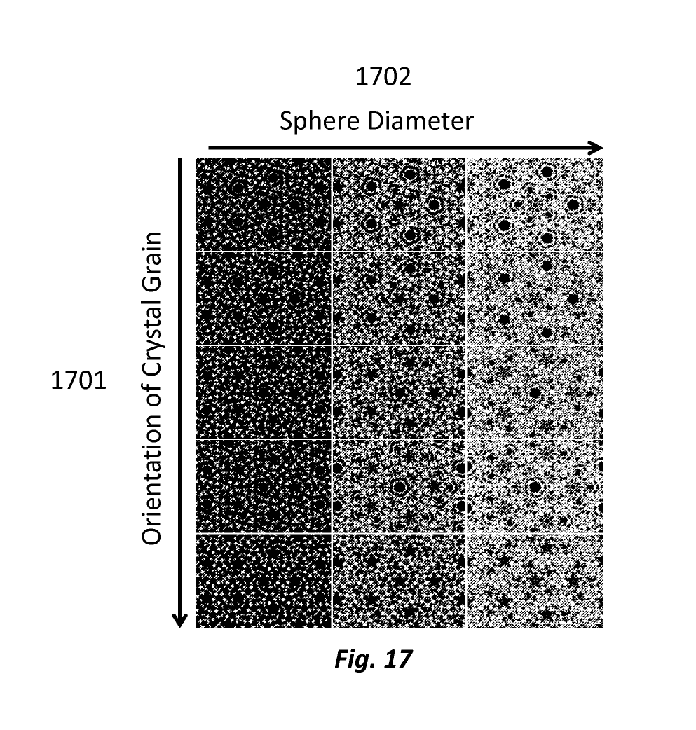

FIG. 17 shows modeled patterns of 15 different quasicrystalline metasurfaces created with five different angles of depositions at φ=72° increments, according to some embodiments of the present disclosure. The 15 different images of the quaiscrystalline metasurfaces vary in orientation of crystal grain 1701 and sphere diameter 1702. Grain orientation refers to the offset angle between the coordinate system in which the quasicrystal lattice is described and angles of deposition. As this offset angle between the orientation of the crystal grain 1701 and the angles of deposition is increased, the projected patterns transition between different versions of quasicrystal. The base pattern includes a Penrose tiling generated using the “kite and dart” method applied n=9 times to an initial “sun” configuration (a pentagonal arrangement of five “kites”). The “kite and dart” method uses two quadrilaterals (a “kite” and a “dart”) as tilings, and is one of three known methods to construct a Penrose tiling. Following a set of rules, these tilings can be sequentially replaced by smaller “kites” and “darts”, increasing the complexity of the pattern upon each iteration. The sphere diameter 1702 can also be varied such that a smaller sphere diameter results in a larger distance between the surfaces of the spheres, and a larger sphere diameter results in a smaller distance between the surfaces of the sphere.

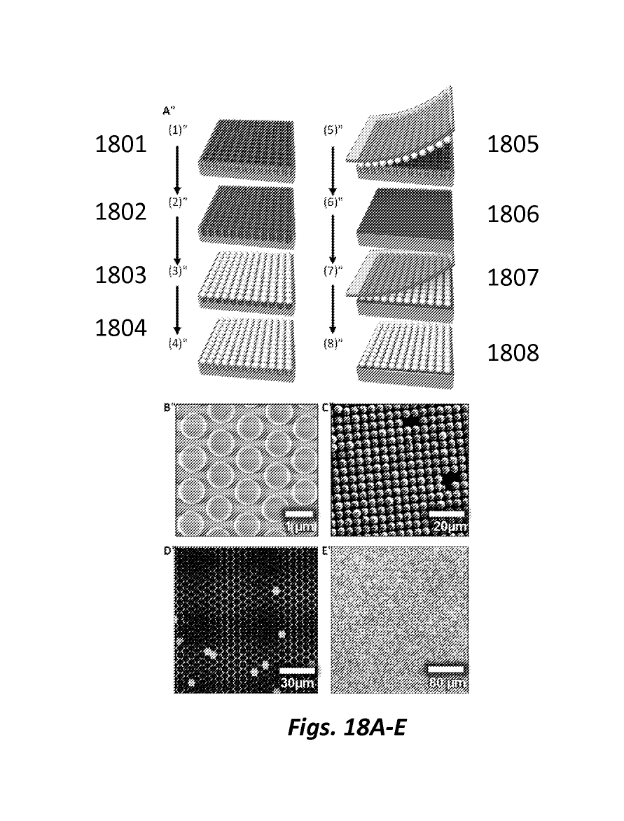

FIGS. 18A-E show a fabrication process and templated spheres, according to some embodiments of the present disclosure.

FIG. 18A shows a fabrication process for templating spheres, according to some embodiments. The first step for templating spheres 1801 includes etching holes into a substrate (e.g., silicon wafer). In some embodiments, to prepare the templates, optical masks are first defined by direct write photolithography (e.g., 2-μm resolution), and then the templates are patterned onto a silicon wafer by a reduction (e.g., 5×) with an integrated circuit manufacturing device (e.g., an i-line stepper) that uses projection lithography and has approximately a 0.5-μm resolution. Using more sophisticated systems for photolithography (e.g., systems using deep ultraviolet light or electron beam lithography), allow for templates with resolution down to ˜100 nm or lower. A reactive ion etch (RIE) is then performed (e.g., with SF₆) to make circular holes with a desired depth and diameter (e.g., a depth of 2 μm, each with a diameter of 1.4 μm). In some embodiments, for proper template-directed self-assembly, the holes are deeper than the radius of the sphere, and the diameter of the holes should be approximately 90% of the diameter of the sphere.

The second step 1802 includes assembling the spheres (e.g. made of silica) by filling the holes with a thin layer of adhesive (e.g., polyethyleneimine (PEI)). After application, a swab soaked in water may be used remove excess adhesive, only leaving adhesive inside the holes

The third step 1803 includes rubbing on the spheres onto the template (e.g. with a silicon-based polymer (e.g., Polydimethylsiloxane (PDMS)).

The fourth step 1804 includes calcinating the spheres to remove the adhesive. In some embodiments, the calcinating step can be performed with a butane torch or other heating source sufficient to vaporize the PEI without damaging the spheres.

The fifth step 1805 can include removing spheres with a slab of silicon-based polymer (e.g., PDMS). In some embodiments, to fabricate metasurfaces on the PDMS, computerized techniques for shadow-deposition as described above are used.

The sixth step 1806 can include spin-coating a target substrate with PEI. In some embodiments, spin-coating includes applying a thin film (˜100 nm) of PEI to the target substrate.

The seventh step 1807 can include bringing the substrate in contact with the spheres on the PDMS to transfer spheres from PDMS to the substrate.

The eighth step 1808 can include removing the PEI with etching. In some embodiments, the etching includes a gentle oxygen plasma etch. In some embodiments, to fabricate metasurfaces on the substrate, computerized techniques for shadow-deposition as described above are used. In some embodiments, holes that are ˜90% of the diameter of the spheres are used for transfer. The large contact area between the spheres and adhesive improves the quality of assembly, while the spheres sit high enough in the template so as not to get stuck in the holes during transfer. The fabrication process described above works equally well for all types of arrays, both periodic and non-periodic.

FIGS. 18B-E show templated arrays of spheres arranged in various patterns. FIG. 18B shows a hexagonal array, FIG. 18C shows a square array, FIG. 18D shows a hexagonal superlattice, and FIG. 18E shows a quasicrystal.

It will be understood that the particular methods and systems described herein are shown by way of illustration only and not as limitations. As will be understood by those skilled in the art, the principles and features described herein may be employed in various and numerous embodiments without departing from the scope of the invention.

1. A computerized method of determining operation parameters for the shadow cast fabrication of micro or nanostructures, the fabrication process using deposition from at least one source over an array of particles, wherein the deposition produces overlapping shadows masking the substrate, the method comprising:
receiving, at a computing device, a first set of parameter inputs defining particle properties and deposition properties in a shadow cast fabrication, wherein the parameter inputs include one or more of particle size, gap between the particles, location of the particles, and location of the at least one source;
generating, by the computing device, data corresponding to a first image for display on a display device based on the first set of parameters;
receiving, by the computing device, at least one incremental parameter input that modifies or adds to the first set of parameter inputs;
dynamically generating, by the computing device, data corresponding to at least one second image for display on the display device based on the at least one incremental parameter input;
receiving, by the computing device, an indication that the at least one second image corresponds to a shape ready for fabrication; and
generating, by the computing device, an output set of fabrication parameters corresponding to the shape ready for fabrication.

2. The computerized method of claim 1, further comprising transmitting the output set of fabrication parameters to a fabrication machine for fabrication of the shape.

3. The computerized method of claim 1, wherein the gap between the particles corresponds to parameters comprising gas flow rate, RF power, length of etch.

4. The computerized method of claim 1, wherein the location of the at least one source comprises at least one angle.

5. The computerized method of claim 4, wherein the at least one angle is adjustable.

6. The computerized method of claim 1, wherein the location of the particles define one of an aperiodic and a quasi-periodic structure.

7. The computerized method of claim 1, wherein the output parameters comprise at least one of a diameter of the particle, an etch time, and one or more deposition angles.

8. A system determining operation parameters for the shadow cast fabrication of micro or nanostructures, the fabrication process using deposition from at least one source over an array of particles, wherein the deposition produces overlapping shadows masking the substrate, the system comprising:
a processor; and
a memory coupled to the processor and including computer-readable instructions that, when executed by a processor, cause the processor to:
receive a first set of parameter inputs defining particle properties and deposition properties in a shadow cast fabrication, wherein the parameter inputs include one or more of particle size, gap between the particles, location of the particles, and location of the at least one source;
generate data corresponding to a first image for display on a display device based on the first set of parameters;
receive at least one incremental parameter input that modifies or adds to the first set of parameter inputs;
dynamically generate data corresponding to at least one second image for display on the display device based on the at least one incremental parameter input;
receive an indication that the at least one second image corresponds to a shape ready for fabrication; and
generate an output set of fabrication parameters corresponding to the shape ready for fabrication.

9. The system of claim 8, wherein the gap between the particles corresponds to parameters comprising gas flow rate, RF power, length of etch.

10. The system of claim 8, wherein the location of the at least one source comprises at least one angle.

11. The system of claim 10, wherein the at least one angle is adjustable.

12. The method of claim 10, wherein the output set of fabrication parameters comprise at least one of a diameter of the particle, an etch time, and one or more deposition angles.

13. The system of claim 8, wherein the location of the particles define one of an aperiodic and a quasi-periodic structure.

14. The method of claim 1, wherein the method of claim 1 is being used to fabricate metasurfaces, the method of fabricating metasurfaces comprising:
depositing particles on a substrate;
performing an isotropic etch to form a gap between the particles;
mounting the substrate on a rotation stage; and
exposing the substrate to at least one deposition source based on at least one of the size of the particles, the gap between the particles and the location of the at least one source.

15. The method of claim 14, wherein the particles comprise polystyrene.

16. The method of claim 1, wherein the method of claim 1 is being used to fabricate metasurfaces, the method of fabricating metasurfaces, comprising:
etching holes into a substrate;
placing particles into the holes;
transferring the particles to a target material;
mounting the target material on a rotation stage; and
exposing the target material to at least one deposition source based on at least one of the size of the particles, the gap between the particles and the location of the at least one source.

17. The method of claim 16, wherein the target material comprises one of Polydimethylsiloxane (PDMS) and a silicon wafer.

18. The method of claim 16, wherein the particles comprise a diameter smaller than a diameter of the holes.

19. The method of claim 17, wherein the diameter of the particles is approximately 90% of the diameters of the holes.

20. The method of claim 16, wherein the particles comprise silica.

21. The method of claim 16, wherein placing the particles into the holes further comprises:
rubbing adhesive onto the template prior to placing the particles into the holes; and
removing the adhesive after placing the particles into the holes by applying a heating source sufficient to vaporize the adhesive without damaging the particles.

22. The method of claim 21, where the adhesive is polyethyleneimine (PEI).
